(19) United States
(12) Patent Application Publication
(10) Pub. No.: US 2024/0224670 A1
(43) Pub. Date: Jul. 4, 2024

(54) DISPLAY DEVICE

(71) Applicant: Samsung Display Co., Ltd., Yongin-si (KR)

(72) Inventors: JUNG SUK BANG, Yongin-si (KR); JANGMI KANG, Yongin-si (KR); TAEHYUN KIM, Yongin-si (KR); DONG-HOON LEE, Yongin-si (KR)

(21) Appl. No.: 18/544,204

(22) Filed: Dec. 18, 2023

(30) Foreign Application Priority Data
Dec. 28, 2022 (KR) 10-2022-0186819

(51) Int. Cl. H10K 59/131

(52) U.S. Cl. CPC H10K 59/131

(57) ABSTRACT

A display device includes: a substrate having a first portion and a second portion adjacent to the first portion in a first direction; a plurality of first pixels; and a plurality of second pixels: a plurality of light emitters comprising a plurality of light emitting elements and arranged in the first direction; a plurality of circuits comprising a plurality of transistors arranged in the first direction; a plurality of first extension lines connected to the circuit units; and a plurality of second extension lines connected to the first extension lines and the light emitters, wherein in an order of the circuits in a direction away from the first portion, a length of each of the first extension lines connected to k+1-th circuits is different from that of each of the first extension lines connected to k-th circuits, and k is a natural number greater than 1.

### CROSS-REFERENCE TO RELATED APPLICATION

The present application claims priority to and the benefit of Korean Patent Application No. 10-2022-0186819, filed on Dec. 28, 2022, in the Korean Intellectual Property Office, the entire content of which is incorporated herein by reference.

### BACKGROUND

### 1. Field

Aspects of some embodiments of the present disclosure herein relate to a display device.

### 2. Description of the Related Art

An electronic device that displays images to a user, e.g., a smartphone, a digital camera, a laptop computer, a navigation unit, and a smart television, includes a display device for displaying images. The display device generates images to display the generated images to the user through a display screen.

The display device includes a display panel for displaying images. The display panel may include a display area that displays images to the user and a non-display area that does not display images.

In recent years, research for reducing the non-display area in the display panel have been performed according to market demand. At the same time, research for increasing the display area at which images are displayed to the user have been performed.

The above information disclosed in this Background section is only for enhancement of understanding of the background and therefore the information discussed in this Background section does not necessarily constitute prior art.

### SUMMARY

Aspects of some embodiments of the present disclosure include a display device in which a display area extends to an upper portion of a driving unit to reduce a non-display area.

According to some embodiments of the present disclosure, a display device includes: a substrate having a first portion and a second portion adjacent to the first portion in a first direction; a plurality of first pixels on the first portion; and a plurality of second pixels on the second portion. Here, the second pixels include: a plurality of light emitting units including a plurality of light emitting elements and arranged in the first direction; a plurality of circuit units including a plurality of transistors and arranged in the first direction; a plurality of first extension lines connected to the circuit units; and a plurality of second extension lines connected to the first extension lines and the light emitting units. Also, in an order of the circuit units in a direction away from the first portion, a length of each of the first extension lines connected to k+1-th circuit units is different from that of each of the first extension lines connected to k-th circuit units, and k is a natural number greater than about 1.

According to some embodiments of the present disclosure, a display device includes: a substrate having a first portion and a second portion adjacent to the first portion in a first direction; and a plurality of pixels on the first portion and the second portion. Here, each of the pixels on the second portion among the pixels includes: a plurality of light emitting units including a plurality of light emitting elements and arranged in the first direction; a plurality of circuit units including a plurality of transistors and arranged in the first direction; a plurality of first extension lines connected to the circuit units; and a plurality of second extension lines connected to the first extension lines and the light emitting units. Also, in an order of the circuit units in a direction away from the first portion, a length of each of the first extension lines connected to k-th circuit units is less than that of each of the second extension lines connected to k-th light emitting units, and k is a natural number greater than about 1.

### BRIEF DESCRIPTION OF THE DRAWINGS

The accompanying drawings are included to provide a further understanding of some embodiments according to the present disclosure, and are incorporated in and constitute a part of this specification. The drawings illustrate aspects of some embodiments of the present disclosure and, together with the description, serve to explain aspects of some embodiments of the present disclosure. In the drawings:

FIG. 1 is a block diagram representing a display device according to some embodiments of the present disclosure;

FIG. 2 is an equivalent circuit diagram representing a pixel according to some embodiments of the present disclosure;

FIG. 3 is a schematic plan view illustrating a display panel according to some embodiments of the present disclosure;

FIG. 4 is an enlarged plan view illustrating a first area AA1 of FIG. 3 according to some embodiments of the present disclosure;

FIG. 5 is a view illustrating a cross-section of a first pixel in FIG. 4 according to some embodiments of the present disclosure;

FIG. 6 is a cross-sectional view taken along line I-I′ of FIG. 4 according to some embodiments of the present disclosure;

FIGS. 7A to 7D are plan views illustrating aspects of a pixel element layer in FIG. 6 according to some embodiments of the present disclosure;

FIGS. 8A to 8H are views for explaining first extension lines connected to circuit units according to some embodiments of the present disclosure;

FIGS. 9A to 9H are views for explaining second extension lines connected to the circuit units according to some embodiments of the present disclosure;

FIG. 10 is a view illustrating light emitting units located on a second portion according to some embodiments of the present disclosure; and

FIG. 11 is a conceptual view for explaining a connection relationship between the light emitting units and the circuit units according to some embodiments of the present disclosure.

### DETAILED DESCRIPTION

Aspects and features of some embodiments of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will more fully convey the scope of embodiments according to the present disclosure to those skilled in the art. Further, the present disclosure is only defined by scopes of claims. Like reference numerals refer to like elements throughout.

It will also be understood that when a layer is referred to as being “on” another layer or substrate, it can be directly on the other layer or substrate, or intervening layers may also be present. In contrast, when an element is referred to as being “directly on” another element or layer, there are no intervening elements or layers present. As used herein, the term “and/or” includes any and all combinations of one or more of the associated listed items.

Spatially relative terms, such as “below”, “beneath”, “lower”, “above”, “upper” and the like, may be used herein for ease of description to describe one element or feature's relationship to another element(s) or feature(s) as illustrated in the figures. The spatially relative terms should be understood as terms which include different directions of configurative elements in addition to directions illustrated in the figures when using or operating embodiments according to the present disclosure. Like reference numerals refer to like elements throughout.

It will be understood that although the terms of first and second are used herein to describe various elements and/or sections, these elements and/or sections should not be limited by these terms. These terms are only used to distinguish one element, component, or section from another element, component, or section. Accordingly, a first element, a first component, or a first section that will be described below may be a second element, a second component, or a second section within the technical idea of the present disclosure.

The embodiments in the detailed description will be described with schematic cross-sectional views and/or plan views as illustrative views of aspects of some embodiments of the present disclosure. Accordingly, shapes of the illustrative views may be modified according to manufacturing techniques and/or allowable errors. Therefore, the embodiments of the present disclosure are not limited to the specific shape illustrated in the figures, but may include other shapes that may be created according to manufacturing processes. Areas illustrated in the drawings have general properties, and are used to illustrate a specific shape of a semiconductor package region. Thus, this should not be construed as limited to the scope of embodiments according to the present disclosure.

Hereinafter, aspects of some embodiments according to the present disclosure will be described in more detail with reference to the accompanying drawings.

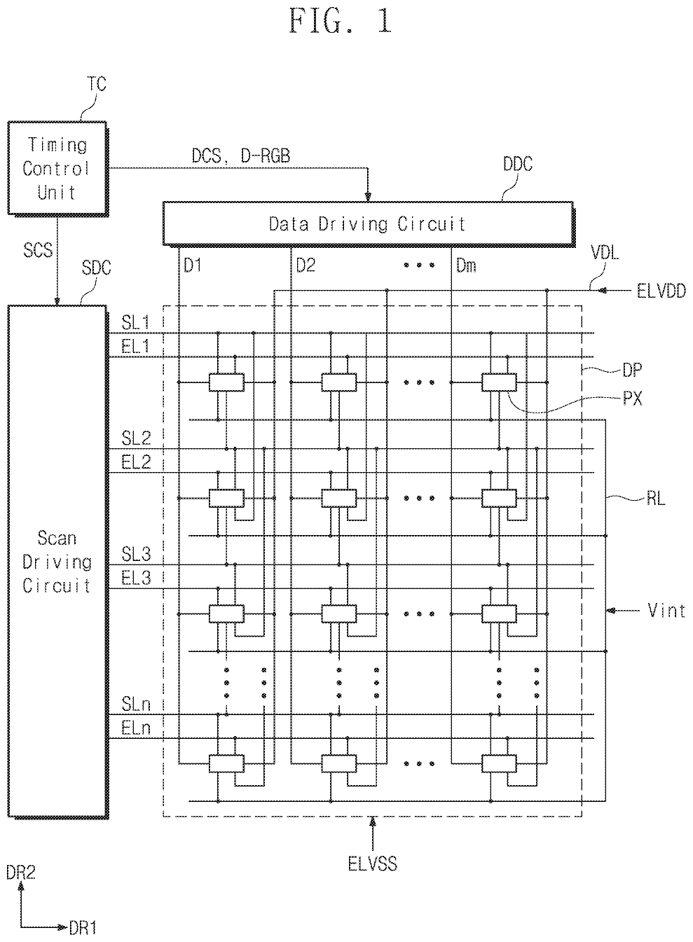

FIG. 1 is a block diagram representing a display device according to some embodiments of the present disclosure.

The display device according to some embodiments of the present disclosure may be a semiconductor device including at least one semiconductor. The display device includes a timing control unit (or timing controller or timing control circuit) TC, a scan driving circuit SDC, a data driving unit (or data driver or data driving circuit) DDC, and a display panel DP. The display panel DP displays images according to an electric signal (e.g., a data signal).

In the present disclosure, the display panel DP is described as an organic light emitting display panel as an example. However, this is merely illustrative, and the display panel DP according to some embodiments of the present disclosure may include various embodiments.

The timing control unit TC receives input image signals and converts a data format of the input image signals to be matched with specifications of an interface with the scan driving circuit SDC, thereby generating image data D-RGB. The timing control unit TC outputs the image data D-RGB and various control signals DCS and SCS.

The scan driving circuit SDC receives a scan control signal SCS from the timing control unit TC. The scan control signal SCS may include a vertical start signal that starts an operation of the scan driving circuit SDC and a clock signal that determines an output time of signals.

The scan driving circuit SDC generates a plurality of scan signals and

sequentially outputs the scan signals to a plurality of scan lines SL1 to SLn. Also, the scan driving circuit SDC generates a plurality of light emission control signals in response to the scan control signal SCS and outputs the light emission control signals to a plurality of light emitting lines EL1 to ELn.

Although the scan signals and the light emission control signals are outputted from one scan driving circuit SDC in FIG. 1, the embodiments of the present disclosure are not limited thereto. According to some embodiments of the present disclosure, the scan driving circuit SDC may divide and output scan signals and divide and output light emission control signals. Also, according to some embodiments of the present disclosure, a driving circuit generating and outputting scan signals and a driving circuit generating and outputting light emission control signals may be separately distinguished.

The data driving circuit DDC receives the data control signal DCS and the image data D-RGB from the timing control unit TC. The data driving circuit DDC converts the image data D-RGB into data signals and outputs the data signals to the data lines DL1 to DLm. The data signals are analog voltages corresponding to gray values of the image data D-RGB.

The display panel DP includes scan lines SL1 to SLn, light emitting lines EL1 to ELn, data lines DL1 to DLm, and pixels PX. The scan lines SL1 to SLn may each extend in the first direction DR1 and may be arranged in a second direction DR2 crossing the first direction DR1.

Each of the plurality of light emitting lines EL1 to ELn may be arranged in parallel to the corresponding scan line of the scan lines SL1 to SLn. The data lines DL1 to DLm cross the scan lines SL1 to SLn in an insulating manner.

Each of the plurality of pixels PX is connected to the corresponding scan line of the scan lines SL1 to SLn, the corresponding light emitting line of the light emitting lines EL1 to ELn, and the corresponding data line of the data lines DL1 to DLm.

Each of the pixels PX receives a first power voltage ELVDD and a second power voltage ELVSS having a level less than that of the first power voltage ELVDD. Each of the pixels PX is connected to a power line PL to which the first power voltage ELVDD is applied. Each of the pixels PX is connected to an initialization line RL receiving an initialization voltage Vint.

Each of the pixels PX may be electrically connected to three scan lines. As illustrated in FIG. 1, the pixels in a second pixel row may be connected to the first to third scan lines SL1 to SL3.

Also, the display panel DP may further include a plurality of dummy scan lines. The display panel DP may further include a dummy scan line connected to the pixels PX in a first pixel row and a dummy scan line connected to the pixels PX in a n-th pixel row. Also, the pixels (hereinafter, referred to as pixels in a pixel row) connected to one data line of the data lines DL1 to DLm may be connected to each other. For example, two neighboring pixels of the pixels in the pixel row may be electrically connected to each other. However, this is merely illustrative. The connection relationship between the pixels PX according to some embodiments of the present disclosure may be variously designed. However, the embodiments of the present disclosure are not limited thereto.

Each of the pixels PX includes an organic light emitting diode and a pixel driving circuit controlling light emission of the organic light emitting diode. The pixel driving circuit may include one or more thin-film transistors, and one or more capacitors.

According to some embodiments, at least one of the scan driving circuit SDC or the data driving circuit DDC may include thin-film transistors provided through the same process as the pixel driving circuit. For example, all of the scan driving circuit SDC and the data driving circuit DDC may be mounted to the display panel DP. Alternatively, one of the scan driving circuit SDC and the data driving circuit DDC may be mounted to the display panel DP, and the other may be provided as a separate circuit board that is independent from the display panel DP and connected to the display panel DP.

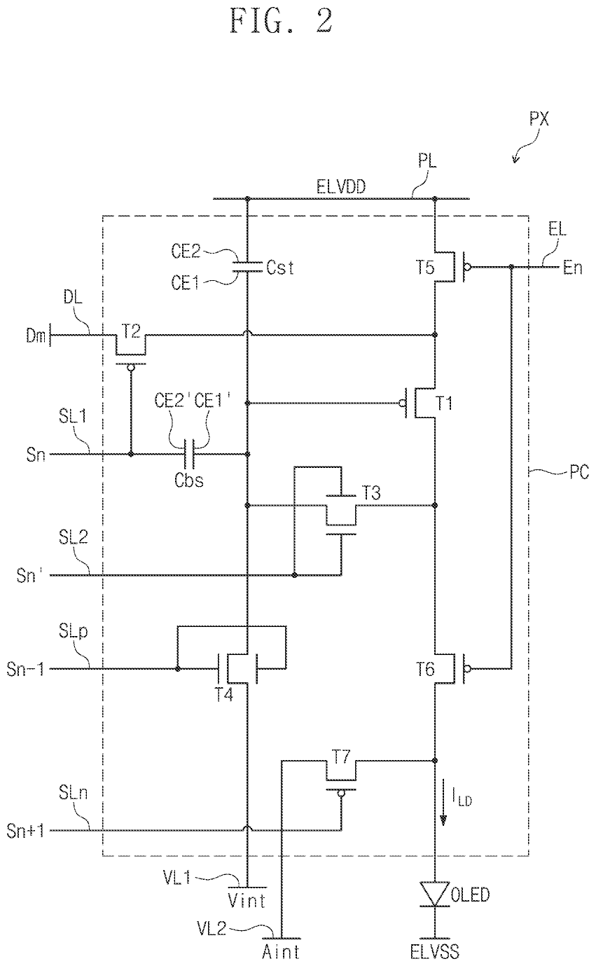

FIG. 2 is an equivalent circuit diagram of the pixel according to some embodiments of the present disclosure.

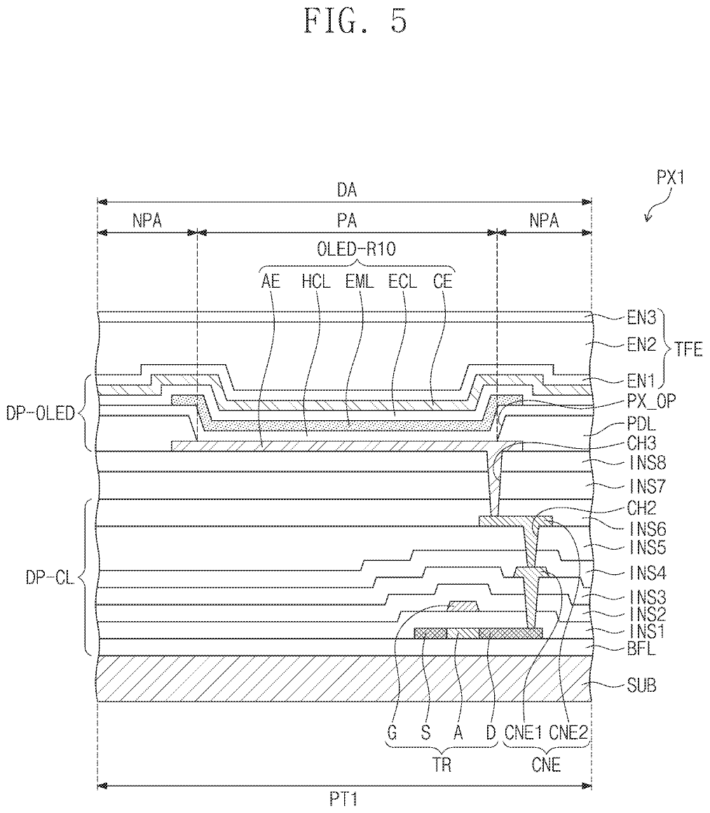

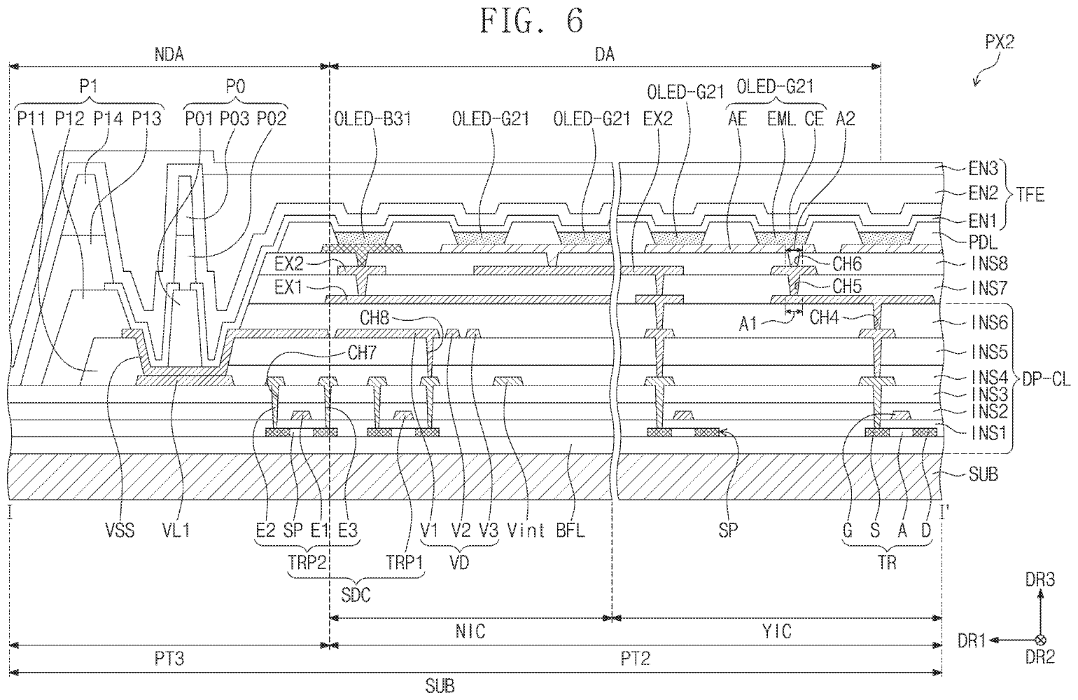

FIG. 2 illustrates an equivalent circuit diagram of one pixel PX of the plurality of pixels PX. The pixel PX may include an organic light emitting diode OLED and a pixel circuit PC. The organic light emitting diode OLED may be a component contained in a display element layer DP-OLED that will be described later in FIGS. 5 and 6, and the pixel circuit PC may be a component contained in a circuit element layer CP-CL that will be described in more detail later with respect to FIGS. 5 and 6.

The pixel circuit CC may include a plurality of thin-film transistors T1 to T7 and a storage capacitor Cst. The plurality of thin-film transistors T1 to T7 and the storage capacitor Cst may be electrically connected to signal lines SL1, SL2, SLp, SLn, EL, and DL, a first initialization voltage line VL1, a second initialization voltage line VL2 (or an anode initialization voltage line), and a driving voltage line PL. According to some embodiments, at least one of the above-described lines, e.g., the driving voltage line PL, may be shared by neighboring pixels PX.

The plurality of thin-film transistors T1 to T7 may include a driving thin-film transistor T1, a switching thin-film transistor T2, a compensation thin-film transistor T3, a first initialization thin-film transistor T4, an operation control thin-film transistor T5, a light emission control thin-film transistor T6, and a second initialization thin-film transistor T7.

The light emitting element OLED may include a first electrode (e.g., an anode electrode or a pixel electrode) and a second electrode (e.g., a cathode electrode or a common electrode). The first electrode of the light emitting element OLED may be connected to the driving thin-film transistor T1 through the light emission control thin-film transistor T6 to receive a driving current ILD, and the second electrode may receive the low power voltage ELVSS. The light emitting element OLED may generate light having luminance corresponding to the driving current ILD.

Some of the plurality of thin-film transistors T1 to T7 may be n-channel MOSFET (NMOS), and the rest may be p-channel MOSFET (PMOS). For example, the compensation thin-film transistor T3 and the first initialization thin-film transistor T4 of the plurality of thin-film transistors T1 to T7 may be the NMOS, and the rest may be the PMOS.

According to some embodiments, the compensation thin-film transistor T3, the first initialization thin-film transistor T4, and the second initialization thin-film transistor T7 of the plurality of thin-film transistors T1 to T7 may be the NMOS, and the rest may be the PMOS. Alternatively, one of the plurality of thin-film transistors T1 to T7 may be the NMOS, and the rest may be the PMOS. Alternatively, all of the plurality of thin-film transistors T1 to T7 may be the NMOS or the PMOS.

The signal lines may include a first scan line SL1 transmitting a first scan signal Sn, a second scan line SL2 transmitting a second scan signal Sn′, a previous scan line SLp transmitting a previous scan signal Sn−1 to the first initialization thin-film transistor T4, a light emission control line EL transmitting a light emission control signal En to the operation control thin-film transistor T5 and the light emission control thin-film transistor T6, a next scan line SLn transmitting a next scan signal Sn+1 to the second initialization thin-film transistor T7, and a data line DL crossing the first scan line SL1 and transmitting a data signal Dm.

The driving voltage line PL may transmit the driving voltage ELVDD to the driving thin-film transistor T1, and the first initialization voltage line VL1 may transmit an initialization voltage Vint that initializes a pixel electrode of each of the driving thin-film transistor T1 and the light emitting element OLED.

The driving thin-film transistor T1 may have a driving gate electrode electrically connected to the storage capacitor Cst, a driving source region electrically connected to the driving voltage line PL through the operation control thin-film transistor T5, and a driving drain region electrically connected to the first electrode of the light emitting element OLED through the light emission control thin-film transistor T6. The driving thin-film transistor T1 may receive the data signal Dm and supply the driving current ILD to the light emitting element OLED according to a switching operation of the switching thin-film transistor T2.

The switching thin-film transistor T2 may have a switching gate electrode connected to the first scan line SL1 transmitting the first scan signal Sn, a switching source region connected to the data line DL, and a switching drain region connected to the driving source region of the driving thin-film transistor T1 and connected to the driving voltage line PL through the operation control thin-film transistor T5. The switching thin-film transistor T2 may be turned on by the first scan signal Sn transmitted through the first scan line SL1 to perform a switching operation of transmitting the data signal Dm transmitted from the data line DL to the driving source region of the driving thin-film transistor T1.

The compensation thin-film transistor T3 may have a compensation gate electrode connected to the second scan line SL2. The compensation thin-film transistor T3 may have a compensation drain region connected to the driving drain region of the driving thin-film transistor T1 and connected to the pixel electrode of the light emitting element OLED through the light emission control thin-film transistor T6. The compensation thin-film transistor T3 may have a compensation source region connected to a first capacitor electrode CE1 of the storage capacitor Cst and the driving gate electrode of the driving thin-film transistor T1. Also, the compensation source region may be connected to a first initialization drain region of the first initialization thin-film transistor T4.

The compensation thin-film transistor T3 may be turned-on according to the second scan signal Sn′ received through the second scan line SL2 and electrically connecting the driving drain region and the driving gate electrode of the driving thin-film transistor T1 to diode-connect the driving thin-film transistor T1.

The first initialization thin-film transistor T4 may have a first initialization gate electrode connected to the previous scan line SLp. The first initialization thin-film transistor T4 may have a first initialization source region connected to a second initialization source region and a first initialization voltage line VL1 of the second initialization thin-film transistor T7. The first initialization thin-film transistor T4 may have a first initialization drain region connected to the first capacitor electrode CE1 the storage capacitor Cst, the compensation source region of the compensation thin-film transistor T3, and the driving gate electrode of the driving thin-film transistor T1. The first initialization thin-film transistor T4 may be turned on by the previous scan signal Sn−1 transmitted through the previous scan line SLp to perform an initialization operation of transmitting the initialization voltage Vint to the driving gate electrode of the driving thin-film transistor T1 and initializing a voltage of the driving gate electrode of the driving thin-film transistor T1.

The operation control thin-film transistor T5 may have an operation control gate electrode connected to the light emission control line EL, an operation source region connected to the driving voltage line PL, and an operation control drain region connected to the driving source region of the driving thin-film transistor T1 and the switching drain region of the switching thin-film transistor T2.

The light emission control thin-film transistor T6 may have a light emission control gate electrode connected to the light emission control line EL, a light emission control source region connected to the driving drain region of the driving thin-film transistor T1 and the compensation drain region of the compensation thin-film transistor T3, and a light emission control drain region electrically connected to a second initialization drain region of the second initialization thin-film transistor T7 and the pixel electrode of the light emitting element OLED.

As the operation control thin-film transistor T5 and the light emission control thin-film transistor T6 are turned on at the same time by the light emission control signal En transmitted through the light emission control line EL, the driving voltage ELVDD is transmitted to the light emitting element OLED, and the driving current ILD flows through the light emitting element OLED.

The second initialization thin-film transistor T7 has a second initialization gate electrode connected to the next scan line SLn, a second initialization drain region connected to the light emission control drain region of the light emission control thin-film transistor T6 and the pixel electrode of the light emitting element OLED, and a second initialization source region connected to the second initialization voltage line VL2 to receive an anode initialization voltage Aint. The second initialization thin-film transistor T7 is turned-on by the next scan signal Sn+1 transmitted through the next scan line SLn to initialize the pixel electrode of the light emitting element OLED.

According to some embodiments, the second initialization thin-film transistor T7 may be connected to the light emission control line EL and driven by the light emission control signal En. The source regions and the drain regions may have positions that are exchanged according to the kind of the transistors (p-type or n-type).

The storage capacitor Cst may include a first capacitor electrode CE1 and a second capacitor electrode CE2. The storage capacitor Cst has a first capacitor electrode CE1 connected to the driving gate electrode of the driving thin-film transistor T1 and a second capacitor CE2 connected to the driving voltage line PL. The storage capacitor Cst may store an electric charge corresponding to a difference between the driving voltage ELVDD and a driving gate electrode voltage of the driving thin-film transistor T1.

A boosting capacitor C110 may include a first capacitor electrode CE1′ and a second capacitor electrode CE2′. The boosting capacitor C110 may have the first capacitor electrode CE1′ connected to the first capacitor electrode CE1 of the storage capacitor Cst and the second capacitor electrode CE2′ to which the first scan signal Sn is provided. The boosting capacitor C110 may compensate a voltage drop of the gate terminal by increasing a voltage of the gate terminal of the driving thin-film transistor T1 at a point in time when the providing of the first scan signal Sn is stopped.

Further details of an operation of each pixel PX according to some embodiments is described below.

When the previous scan signal Sn−1 is supplied through the previous scan line SLp during an initialization period, the first initialization thin-film transistor T4 is turned-on in correspondence to the previous scan signal Sn−1, and the driving thin-film transistor T1 is initialized by the initialization voltage Vint supplied from the first initialization voltage line VL1.

When the first scan signal Sn and the second scan signal Sn′ are supplied through the first scan line SL1 and the second scan line SL2 during a data programming period, the switching thin-film transistor T2 and the compensation thin-film transistor T3 are turned-on in correspondence to the first scan signal Sn and the second scan signal Sn′. Here, the driving thin-film transistor T1 is diode-connected by the turned-on compensation thin-film transistor T3 and forward biased.

Then, a compensation voltage (Dm+Vth, where Vth has a negative value) that is reduced as many as a threshold voltage Vth of the driving thin-film transistor T1 from the data signal Dm supplied from the data line DL is applied to the driving gate electrode of the driving thin-film transistor T1.

The driving voltage ELVDD and the compensation voltage (Dm+Vth) are applied to both ends of the storage capacitor Cst, and electric charges corresponding to a voltage difference between the both ends of the storage capacitor Cst are stored.

The operation control thin-film transistor T5 and the light emission control thin-film transistor T6 are turned-on by the light emission control signal En supplied from the light emission line EL during a light emission period. The driving current ILD is generated in accordance with a voltage difference between the driving voltage ELVDD and the voltage of the driving gate electrode of the driving thin-film transistor T1, and the driving current ILD is supplied to the light emitting diode OLED through the light emission control thin-film transistor T6.

According to some embodiments, at least one of the plurality of thin-film transistors T1 to T7 includes a semiconductor layer containing an oxide, and the rest thereof includes a semiconductor layer containing silicon.

For example, the driving thin-film transistor T1 that directly affects brightness of the display device may include a semiconductor layer made of polycrystalline silicon having high reliability, and through this, the display device having a high resolution may be realized.

Because the oxide semiconductor has high carrier mobility and low leakage current, the oxide semiconductor has a voltage drop that is not great although a driving time thereof is long. That is, because a color variation of an image caused by the voltage drop is not large even during a low frequency driving, a low frequency driving of the oxide semiconductor may be implemented.

As described above, because the oxide semiconductor has an advantage of the low leakage current, the leakage current that flows through the driving gate electrode may be prevented, and power consumption may be relatively reduced at the same time by adopting, as the oxide semiconductor, at least one of the compensation thin-film transistor T3, the first initialization thin-film transistor T4, or the second initialization thin-film transistor T7, which are connected to the driving gate electrode of the driving thin-film transistor T1.

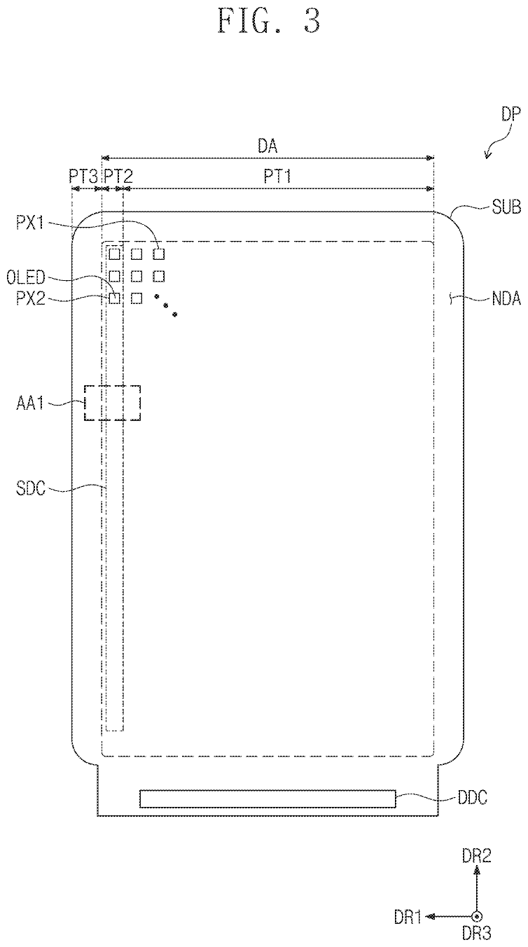

FIG. 3 is a plan view illustrating a display panel according to some embodiments of the present disclosure.

For convenience of description and illustration, some components are omitted in FIG. 3.

For example, although second pixels PX2 located on a second portion PT2 are arranged one by one in the first direction DR1 in FIG. 3, according to some embodiments, a plurality of second pixels PX2 may be arranged on the second portion PT2 in the first direction DR1.

Referring to FIG. 3, the display panel DP may include a substrate SUB, a data driving circuit DDC, and a scan driving circuit SDC.

The display panel DP may include a display area DA and a non-display area NDA. In a plan view (e.g., a direction perpendicular or normal with respect to a display surface of the display panel DP), the display area DA may have a rectangular shape defined by the first direction DR1 and the second direction DR2. However, the embodiments of the present disclosure are not limited thereto. For example, the display area DA may have various shapes such as a circular shape or a polygonal shape. The non-display area NDA may be located adjacent to the display area DA. The non-display area NDA may surround the display area DA (e.g., in a periphery, or outside a footprint of the display area DA).

The substrate SUB may include a first portion PT1, a second portion PT2, and a third portion PT3. The first portion PT1 and the second portion PT2 may overlap the display area DA. For example, in a plan view, the first portion PT1 may have a rectangular shape defined by the first direction DR1 and the second direction DR2.

The second portion PT2 may be located adjacent to the first portion PT1. The second portion PT2 may extend from one side of both sides of the first portion PT1, which are opposed to each other in the second direction DR2. According to some embodiments, the first portion PT1 and the second portion PT2 may be integrated with each other.

The pixels PX may be located on the first portion PT1 and the second portion PT2. The pixels PX may be arranged in the first direction DR1 and the second direction DR2. The pixels PX located on the first portion PT1 may be defined as first pixels PX1. The pixels PX located on the second portion PT2 may be defined as second pixels PX2.

The third portion PT3 may overlap the non-display area NDA. The pixels PX may not be located on the third portion PT3. The third portion PT3 may surround the first portion PT1 and the second portion PT2.

The scan driving circuit SDC may be located at the display area DA. The scan driving circuit SDC may be located at the second portion PT2. The scan driving circuit SDC may be located adjacent to the non-display area NDA. In a plan view, the scan driving circuit SDC may overlap the light emitting elements OLED that will be described later. The light emitting elements OLED located on the scan driving circuit SDC will be described in detail in FIG. 6.

The scan driving circuit SDC may extend in the second direction DR2. According to some embodiments, for example, the scan driving circuit SDC may be provided as two circuits that are distinguished from each other. Two scan driving circuits SDC may be spaced apart from each other in the first direction DR1 with a center of the first portion PT1 therebetween. However, the embodiments of the present disclosure are not limited to the number of scan driving circuits SDC. For example, a relatively greater number of scan driving circuits SDC may be provided.

The data driving circuit DDC may be located at the non-display area NDA. The data driving circuit DDC may be located on the third portion PT3. For example, the data driving circuit DDC may be provided through the same process as the scan driving circuit SDC. However, the embodiments of the present disclosure are not limited thereto. For example, the data driving circuit DDC may be provided as an independent separate circuit board and connected to the display panel DP.

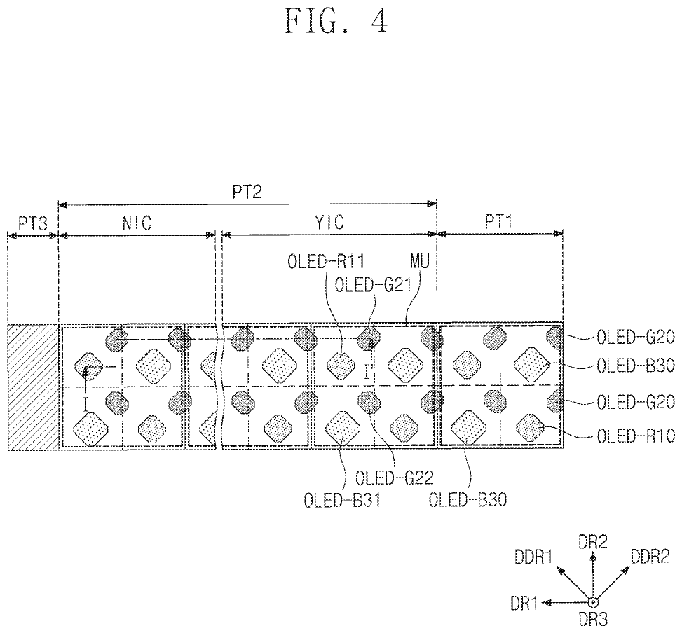

FIG. 4 is an enlarged plan view illustrating a first area AA1 of FIG. 3.

Referring to FIGS. 3 and 4, the plurality of pixels PX may be located on the substrate SUB. The first pixels PX1 may be located at the first portion PT1. The second pixels PX2 may be located at the second portion PT2.

Each of the first pixels PX1 may include a plurality of first light emitting elements OLED-R10, a plurality of second light emitting elements OLED-G20, and a plurality of third light emitting elements OLED-B30.

The first light emitting elements OLED-R10 emit red light, the second light emitting elements OLED-G20 emit green light, and the third light emitting elements OLED-B30 emit blue light.

The first light emitting elements OLED-R10 may be arranged in a first diagonal direction DDR1. The second light emitting elements OLED-G20 may be arranged in the first direction DR1 and the second direction DR2. The third light emitting elements OLED-B30 may be arranged in a second diagonal direction DDR2. The first diagonal direction DDR1 may be defined as a direction crossing the first and second directions DR1 and DR2 on a plane defined by the first direction DR1 and the second direction DR2. The second diagonal direction DDR2 may be defined as a direction crossing the first diagonal direction DDR1.

The first light emitting elements OLED-R10 and the third light emitting elements OLED-B30 may be alternately arranged in the first direction DR1 and the second direction DR2. The second light emitting elements OLED-G20 may be located adjacent to the first light emitting elements OLED-R10 and the third light emitting elements OLED-B30.

Each of the second pixels PX2 may include a light emitting unit (or light emitter) MU. The light emitting units MU may be arranged in the first direction DR1. Each of the light emitting units MU may include a plurality of first light emitting elements OLED-R11, a plurality of second-1 light emitting elements OLED-G21, a plurality of second-2 light emitting elements OLED-G22, and a plurality of third light emitting elements OLED-B31. The first light emitting elements OLED-R11 emit red light, the second-1 light emitting elements OLED-G21 and the second-2 light emitting elements OLED-G22 emit green light, and the third light emitting elements OLED-B31 emit blue light.

The first light emitting elements OLED-R11 may be arranged in the first diagonal direction DDR1. The second-1 light emitting elements OLED-G21 and the second-2 light emitting elements OLED-G22 may be arranged in the first direction DR1. The third light emitting elements OLED-B31 may be arranged in a second diagonal direction DDR2.

The second-1 light emitting elements OLED-G21 and the second-2 light emitting elements OLED-G22 may be spaced apart from each other in the second direction DR2. The second-1 and second-2 light emitting elements OLED-G21 and OLED-G22 may be located adjacent to the first and third light emitting elements OLED-R11 and OLED-B31.

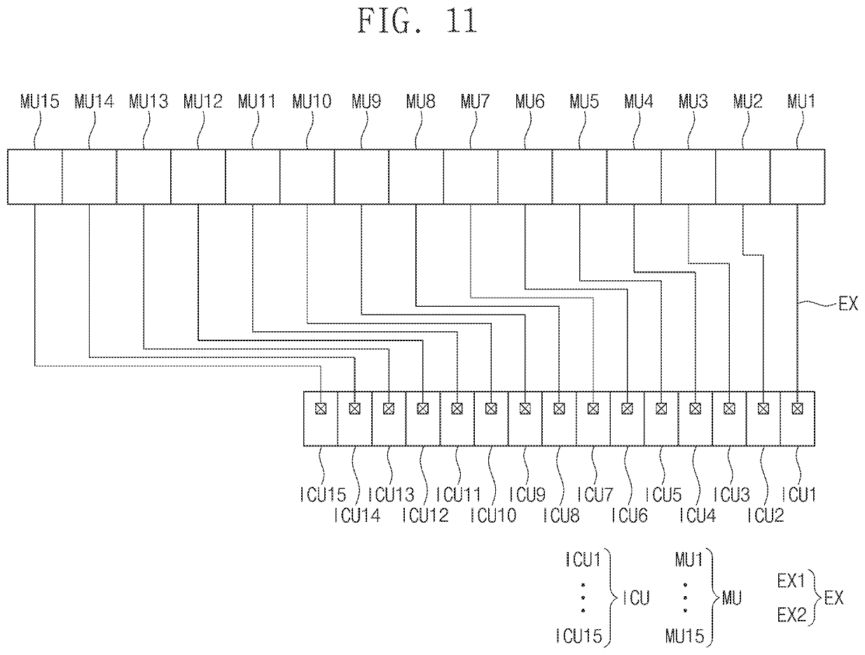

According to some embodiments, the first light emitting elements OLED-R11 of each of the light emitting units MU may be electrically connected to each other. The second-1 light emitting elements OLED-G21 of each of the light emitting units MU may be electrically connected to each other. The second-2 light emitting elements OLED-G22 of each of the light emitting units MU may be electrically connected to each other. The third light emitting elements OLED-B31 of each of the light emitting units MU may be electrically connected to each other. The electrical connection of the light emitting elements emitting the same color will be described in detail in FIGS. 6 and 10.

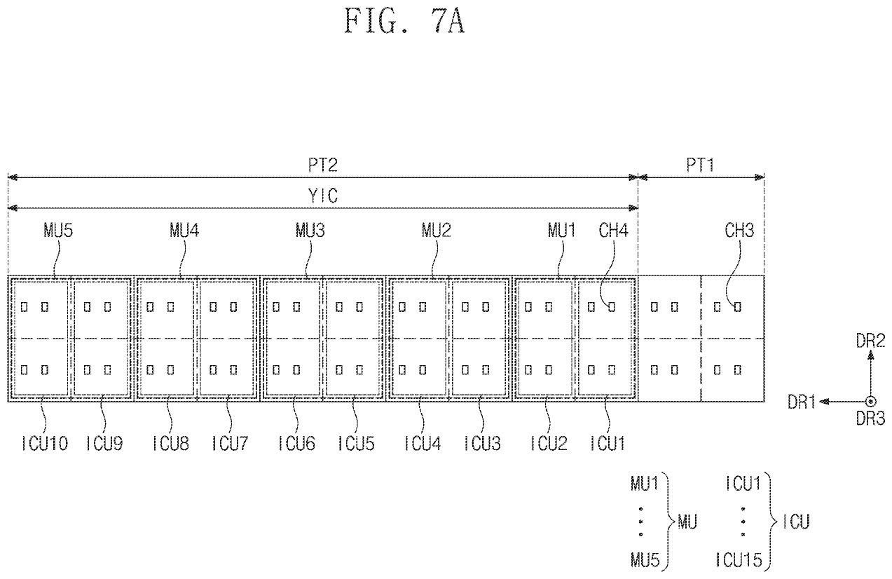

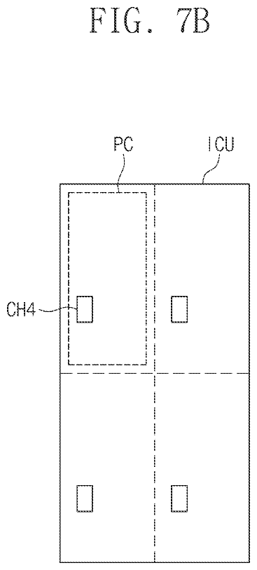

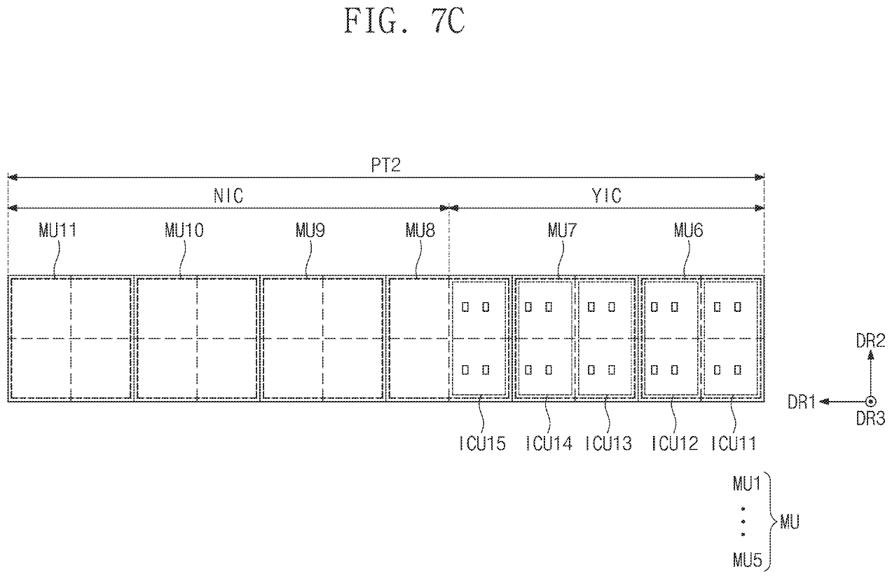

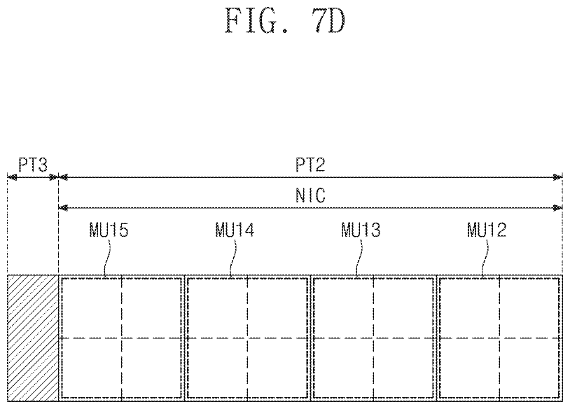

The second portion PT2 may include a second-1 portion YIC and a second-2 portion NIC. The second-1 portion YIC and the second-2 portion NIC may be arranged in the first direction DR1. The second-1 portion YIC may be located adjacent to the first portion PT1. The second-2 portion NIC may be spaced apart from the first portion PT1 more than the second-1 portion YIC. The second-1 portion YIC and the second-2 portion NIC will be described in detail in FIGS. 7A to 7C.

FIG. 5 is a view illustrating a cross-section of the first pixel in FIG. 4 as an example.

Although the first pixel PX1 including the first light emitting element OLED-R10 is described as an example, each of the second light emitting element OLED-G20 and the third light emitting element OLED-B30 may have the same (or substantially the same) configuration as the first light emitting elements OLED-R10.

For example, a transistor TR in FIG. 5 may be the sixth transistor T6 in FIG. 2.

Referring to FIG. 5, the first pixel PX1 may include a transistor TR and a light emitting element OLED-R10.

The light emitting element OLED-R10 may include a first electrode (or an anode) AE, a second electrode (or a cathode) CE, a hole control layer HCL, an electron control layer ECL, and a light emitting layer EML.

The transistor TR and the light emitting device OLED may be located on the substrate SUB. Although one transistor TR is illustrated as an example, according to some embodiments, the first pixel PX1 may include the first to fifth and seventh transistors T1 to T5 and T7 and at least one capacitor in FIG. 2 for driving the light emitting element OLED-R10.

The display area DA may include a light emitting area PA corresponding to each of the first pixels PX1 and a non-light emitting area NPA arranged around the light emitting area PA. The light emitting element OLED-R10 may be located at the light emitting area PA.

A buffer layer BFL may be located on the substrate SUB, and the buffer layer BFL may be an inorganic layer. A semiconductor pattern may be located on the buffer layer BFL. The semiconductor pattern may include polysilicon, amorphous silicon, or a metal oxide.

The semiconductor pattern may be doped with an n-type dopant or a p-type dopant. The semiconductor pattern may include a highly doped area and a lightly doped area. The highly doped area may have conductivity greater than that of the lightly doped area, and according to some embodiments, the highly doped area may serve as a source electrode and a drain electrode of the transistor TR. The lightly doped area may correspond (or substantially correspond) to an active (or a channel) of the transistor.

A source S, an active A, and a drain D of the transistor TR may be provided from the semiconductor pattern. A first insulation layer INS1 may be located on the semiconductor pattern. A gate G of the transistor TR may be located on the first insulation layer INS1. A second insulation layer INS2 may be located on the gate G. A third insulation layer INS3 may be located on the second insulation layer INS2.

A connection electrode CNE may include a first connection electrode CNE1 and a second connection electrode CNE2 for connecting the transistor TR and the light emitting element OLED-R11. The first connection electrode CNE1 may be located on the third insulation layer INS3 and connected to the drain D through a first contact hole CH1 defined in the first to third insulation layers INS1 to INS3.

A fourth insulation layer INS4 may be located on the first connection electrode CNE1. A fifth insulation layer INS5 may be located on the fourth insulation layer INS4. The second connection electrode CNE2 may be located on the fifth insulation layer INS5. The second connection electrode CNE2 may be connected to the first connection electrode CNE1 through a second contact hole CH2 defined in the fourth and fifth insulation layers INS4 and INS5.

A sixth insulation layer INS6 may be located on the second connection electrode CNE2. Layers from the buffer layer BFL to the sixth insulation layer INS6 may be defined as a circuit element layer DP-CL. Each of the first to sixth insulation layers INS1 to INS6 may be an inorganic layer or an organic layer.

A seventh insulation layer INS7 may be located on the sixth insulation layer INS6. An eighth insulation layer INS8 may be located on the seventh insulation layer INS7.

The first electrode AE may be located on the eighth insulation layer INS8. The first electrode AE may be connected to the second connection electrode CNE2 through a third contact hole CH3 defined in the sixth to eighth insulation layer INS6 to INS8. A pixel defining layer PDL in which an opening PX_OP for exposing a predetermined portion of the first electrode AE may be located on the first electrode AE and the eighth insulation layer INS8.

The hole control layer HCL may be located on the first electrode AE and the pixel defining layer PDL. The hole control layer HCL may include a hole transport layer and a hole injection layer.

The light emitting layer EML may be located on the hole control layer HCL. The light emitting layer EML may be arranged in an area corresponding to the opening PX_OP. The light emitting layer EML may include an organic material and/or an inorganic material. The light emitting layer EML may generate one of red light, green light, and blue light.

The electron control layer ECL may be located on the light emitting layer EML and the hole control layer HCL. The electron control layer ECL may include an electron transport layer and an electron injection layer. The hole control layer HCL and the electron control layer ECL may be located on the light emitting area PA and the non-light emitting area NPA in common.

The second electrode CE may be located on the electron control layer ECL. The second electrode CE may be located on the first pixels PX1 in common. A layer on which the light emitting element OLED-R10 is located may be defined as a display element layer DP-OLED.

The light emitting element OLED-R10 may be connected to the pixel circuit PC in FIG. 2 through the sixth transistor T6. That is, the light emitting element OLED-R10 may be connected to the first to fifth transistors T1 to T5, the seventh transistor T7, and the capacitor Cst through the sixth transistor T6.

A thin-film encapsulation layer TFE may be located on the second electrode CE to cover the first light emitting element OLED-R10. The thin-film encapsulation layer TFE may include a first encapsulation layer EN1 located on the second electrode CE, a second encapsulation layer EN2 located on the first encapsulation layer EN1, and a third encapsulation layer EN3 located on the second encapsulation layer EN2.

The first and third encapsulation layers EN1 and EN3 may include an inorganic insulation layer and protect the first pixel PX1 from moisture or oxygen. The second encapsulation layer EN2 may include an organic insulation layer and protect the first pixel PX1 from foreign substances such as dust particles.

A first voltage may be applied to the first electrode AE through the transistor TR, and a second voltage having a level less than that of the first voltage may be applied to the second electrode CE. Here, a hole and an electron, which are injected to the light emitting layer EML, may be coupled to provide an exciton, and, while the exciton is transferred to the ground state, the light emitting element OLED-R10 may emit light.

FIG. 6 is a cross-sectional view taken along the line I-I′ of FIG. 4.

For example, the hole control layer HCL and the electron control layer ECL of the light emitting elements OLED-G21 and OLED-B31 are omitted, and the light emitting elements OLED-G21 and OLED-B31 are simply illustrated by the first electrode AE, the light emitting layer EML, and the second electrode CE.

For example, because the first to eighth insulation layers INS1 to INS8, the buffer layer BFL, the transistors TR, and the thin-film encapsulation layer TFE in FIG. 6 are the same as the first to eighth insulation layers INS1 to INS8, the buffer layer BFL, the transistors TR, and the thin-film encapsulation layer TFE in FIG. 5, descriptions thereof may be omitted or simply provided.

For example, the transistor TR in FIG. 6 may be the sixth transistor T6 in FIG. 2. According to some embodiments, the second pixel PX2 may include the first to fifth and seventh transistors T1 to T5 and T7 and at least one capacitor in FIG. 2 for driving the light emitting elements OLED-G21 and OLED-B31.

For convenience of description, FIG. 6 illustrates some driving transistors TRP1 and TRP2 among the scan driving circuits SDC in FIG. 1.

Referring to FIGS. 4 and 6, each of the first to third insulation layers INS1 to INS3 may extend toward the non-display area NDA. Each of the first to third insulation layers INS1 to INS3 may extend onto an edge adjacent to one side of both sides, which are opposite to each other in the first direction DR1, of the third portion PT3. One side of the third portion PT3 may be defined as a side opposite to the other side adjacent to the second portion PT2.

Each of the fourth to eighth insulation layers INS4 to INS8 may extend toward the non-display area NDA. Each of the fourth to eighth insulation layers INS4 to INS8 may extend onto an edge adjacent to the other side of the third portion PT3.

The display panel DP (refer to FIG. 3) may include a plurality of first extension lines EX1 and a plurality of second extension lines EX2. The first extension lines EX1 may be located on the sixth insulation layer INS6. The first extension lines EX1 may be connected to the second connection electrode CNE2 through a fourth contact hole CH4 defined in the sixth insulation layer INS6. The first extension lines EX1 may be connected to the source S through the first connection electrode CNE1 and the second connection electrode CNE2.

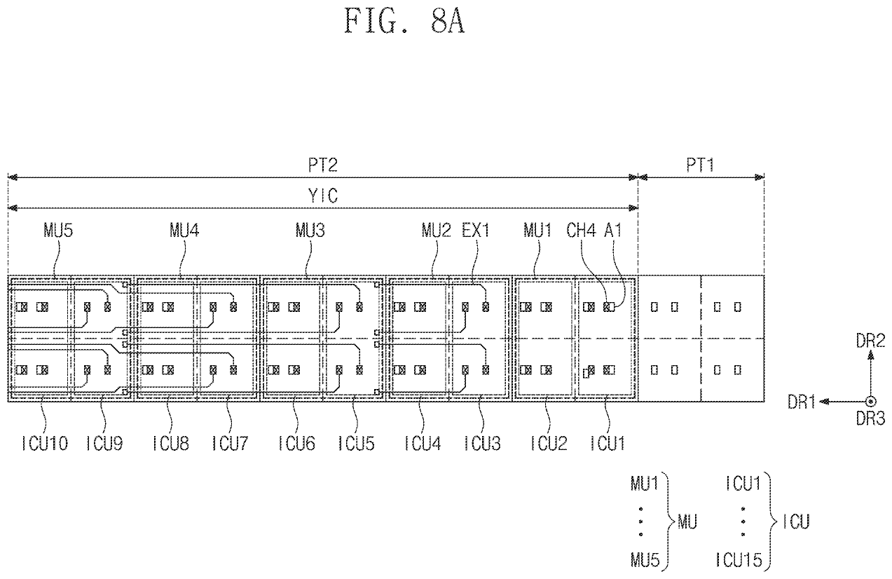

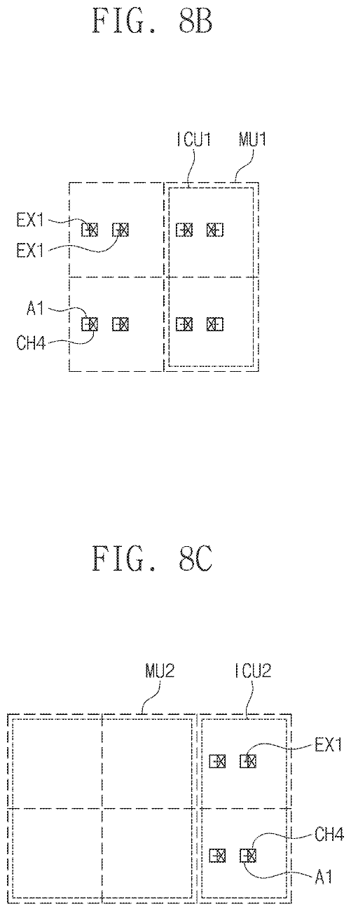

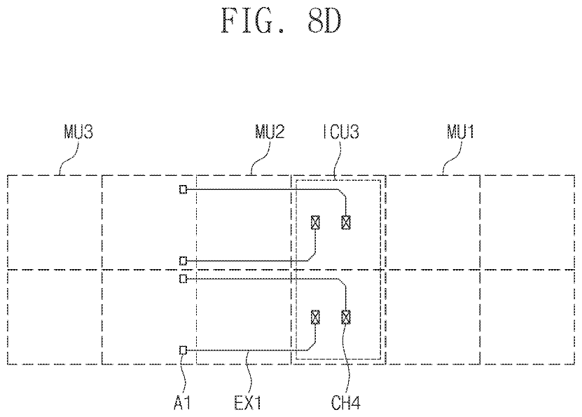

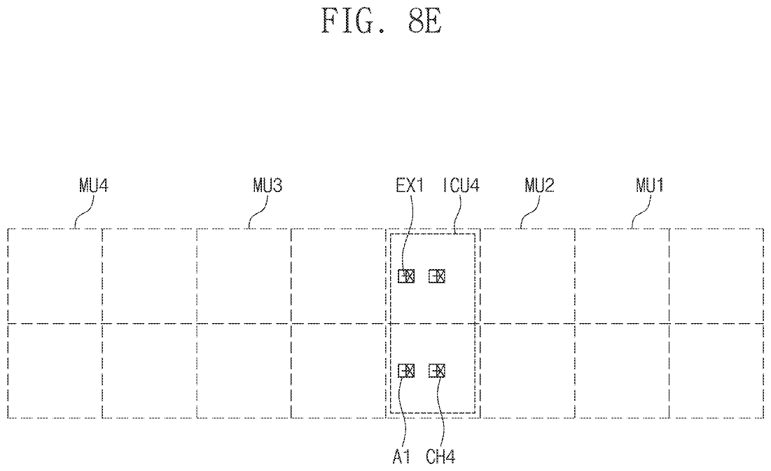

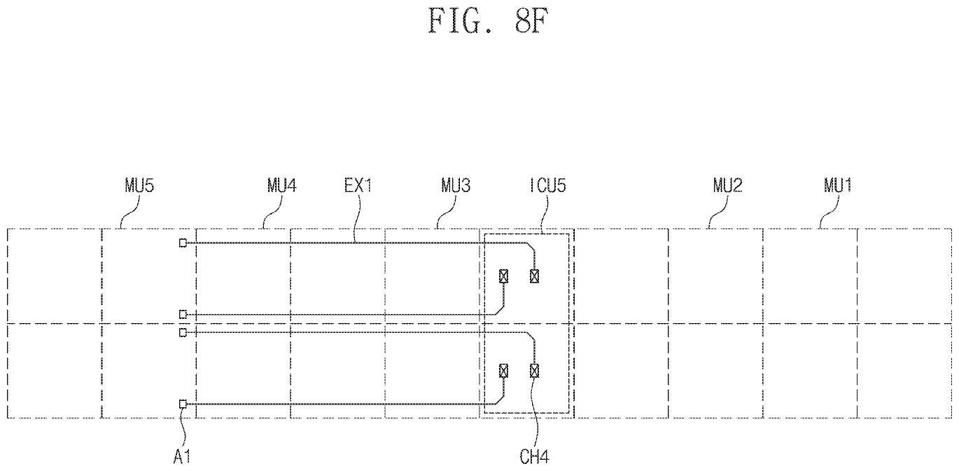

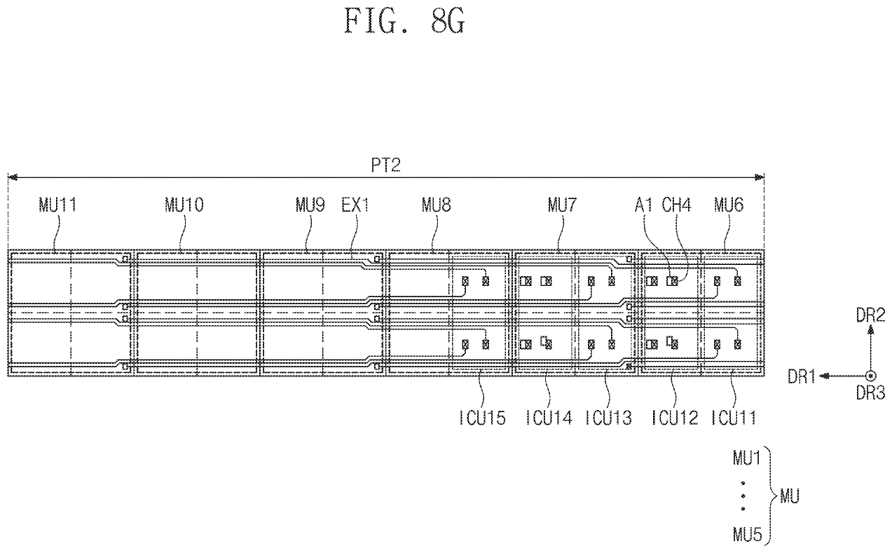

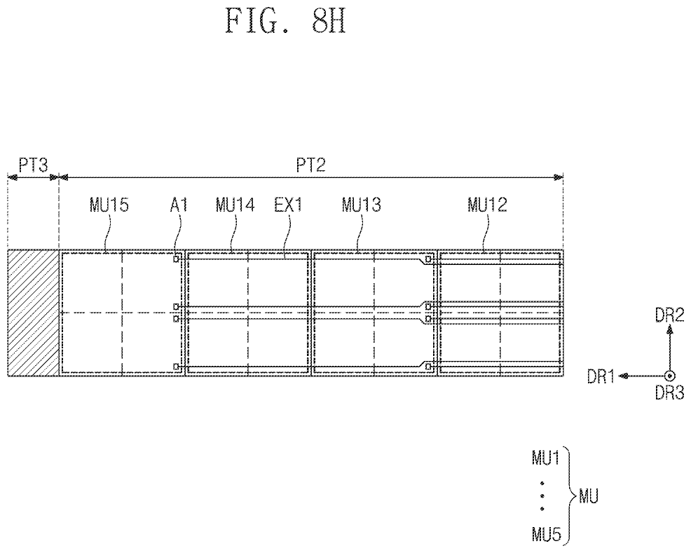

The first extension lines EX1 that are adjacent to each other in the first direction DR1 may have different lengths. The length of each of the first extension lines EX1 may be defined as a portion arranged from the fourth contact hole CH4 to the first area A1. A length variation of the first extension lines EX1 will be described in detail in FIGS. 8A to 8C.

The seventh insulation layer INS7 may be located on the sixth insulation layer INS6 to cover the first extension lines EX. The second extension lines EX2 may be located on the seventh insulation layer INS7. Each of the second extension lines EX2 may be connected to the corresponding first extension line EX1 among the first extension lines EX1 through a fifth contact hole CH5 defined in the seventh insulation layer INS7. The second extension lines EX2 may contact the first area A1 of the first extension lines EX1. The first areas A1 may overlap the fifth contact holes CH5. Each of the second extension lines EX1 may be connected to the source S through the first extension lines EX1, the first connection electrode CNE1 and the second connection electrode CNE2.

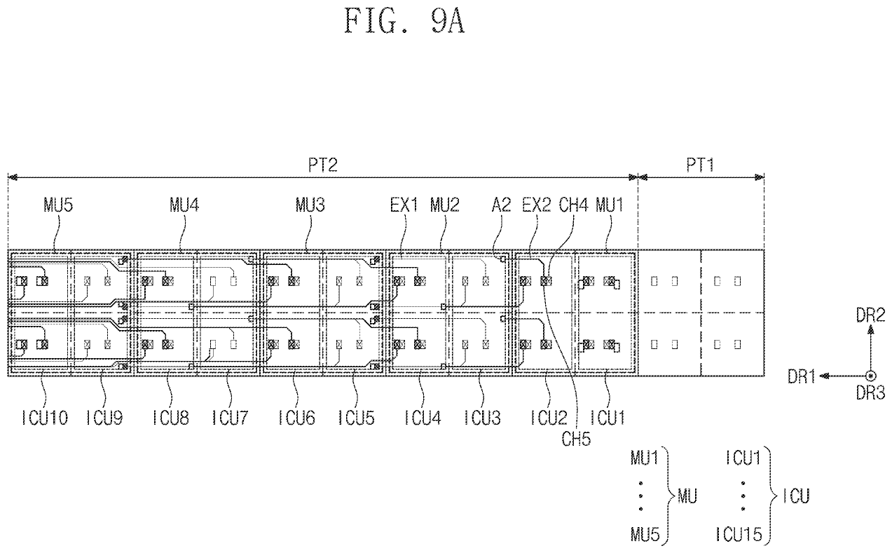

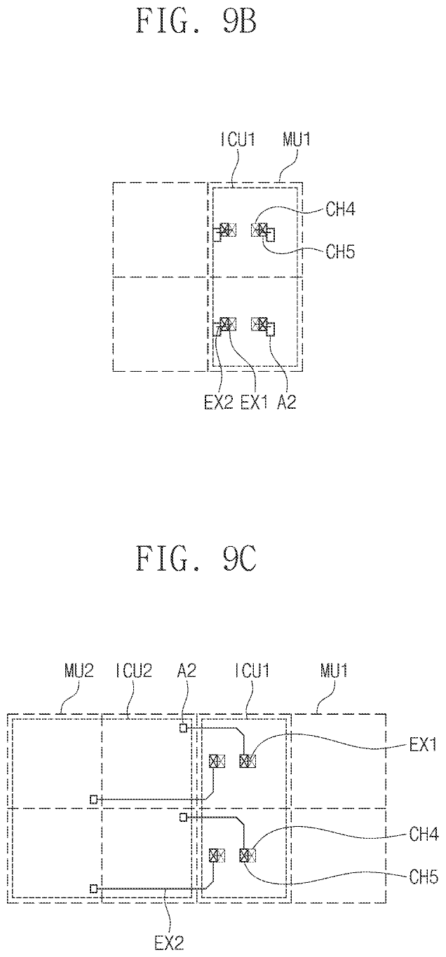

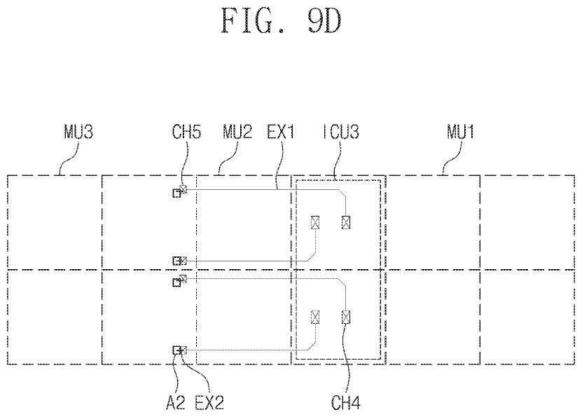

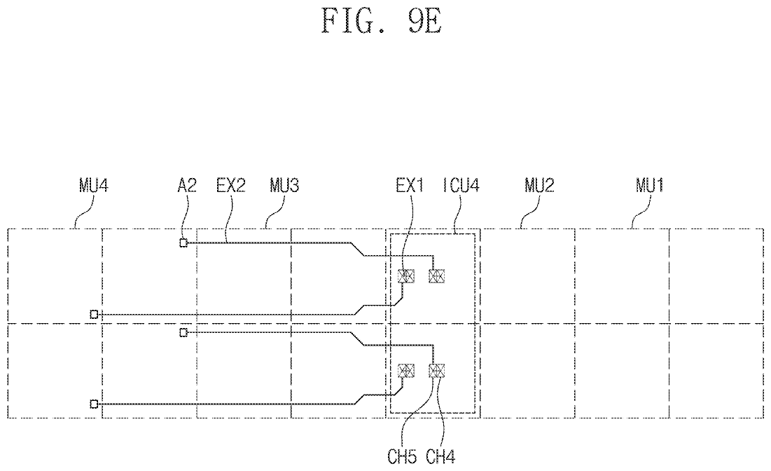

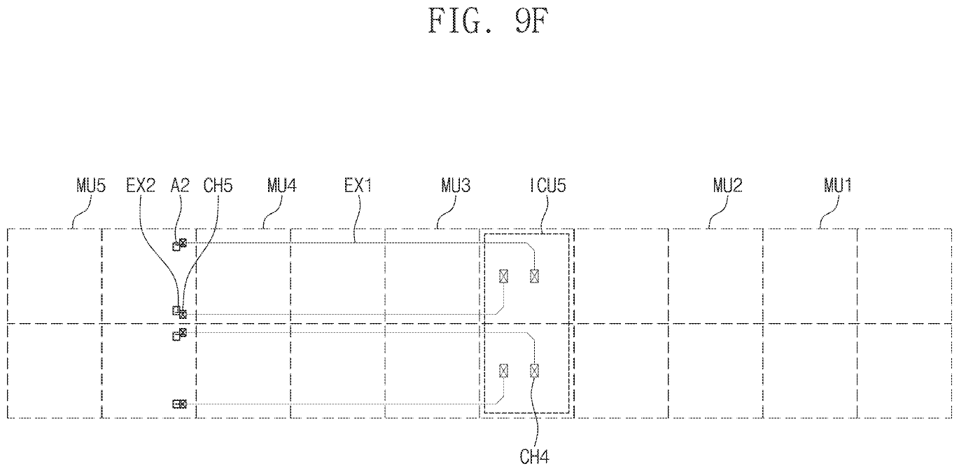

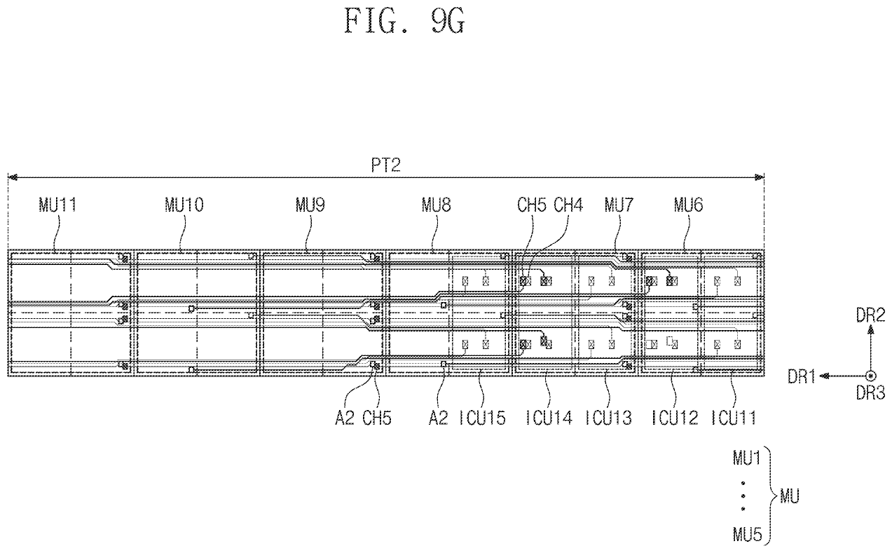

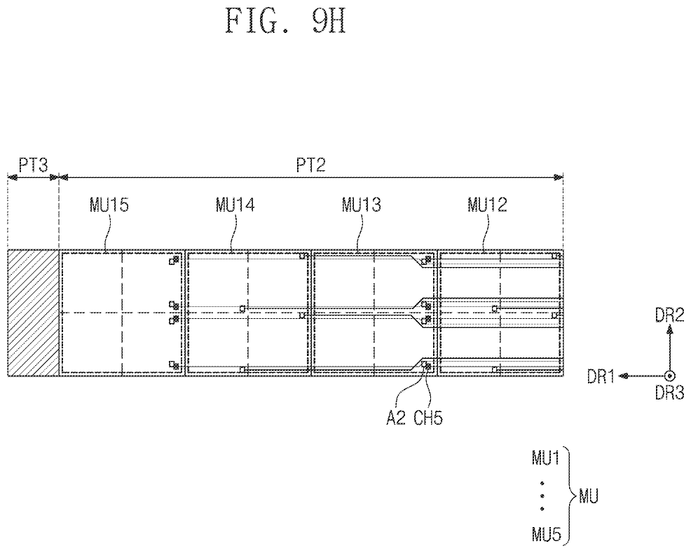

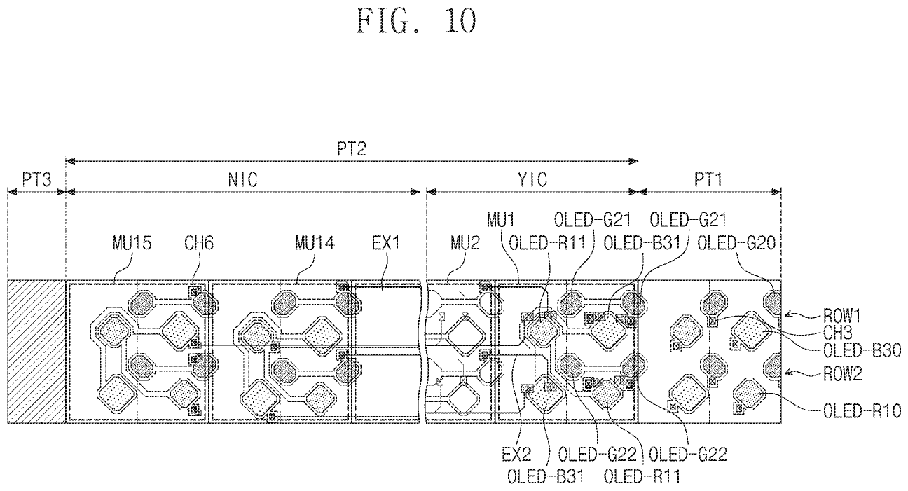

The second extension lines EX2 that are adjacent to each other in the first direction DR1 may have different lengths. The length variation of the second extension lines EX1 will be described in detail in FIGS. 9A to 9C.

The eighth insulation layer INS8 may be located on the seventh insulation layer INS7 to cover the second extension lines EX2. The first electrodes AE may be located on the eighth insulation layer INS8. Each of the first electrodes AE may be connected to the corresponding second extension line EX2 among the second extension lines EX2 through a sixth contact hole CH6 defined in the eighth insulation layer INS8. The first electrodes AE may contact the second area A2 of the second extension lines EX2. The second area A2 may overlap the sixth contact holes CH6. Each of the first electrodes AE may be connected to the corresponding transistor TR among the transistors TR. The length of each of the second extension lines EX2 may be defined as a portion arranged from the fifth contact hole CH5 to the second area A2.

The first electrodes AE may be located on the light emitting layers EML. The light emitting elements OLED that emit the same colors may be connected to each other through one first electrode AE. The light emitting layers EML adjacent to each other among the light emitting layers EML of the light emitting elements OLED that emit the same colors may be connected to each other through the first electrode AE.

For example, the second-1 light emitting elements OLED-G21 may be connected to each other by the first electrode AE of one second-1 light emitting element OLED-G21. The light emitting layers EML of the second-1 light emitting elements OLED-G21 may be located on the first electrode AE of one second-1 light emitting element OLED-G21. However, the embodiments of the present disclosure are not limited thereto. For example, more light emitting layers EML may be located on one first electrode AE. Thus, the light emitting layers EML located on one first electrode AE may be simultaneously controlled. For example, the light emitting layers EML located on one first electrode AE may apply data in common. The second electrode CE2 may be located on the light emitting layers EML. The second electrode CE may be located on the first pixels PX1 in common.

According to some embodiments, the first light emitting elements OLED-R11, the second light emitting elements OLED-G22, and the third light emitting elements OLED-B31 may be connected to each other with the same structure.

The light emitting elements OLED and the transistors TR connected to the light emitting elements OLED may not overlap each other. The light emitting elements OLED may be spaced apart from the transistors TR. Arrangement between the light emitting elements OLED and the transistors TR will be described in detail in FIGS. 7A to 10.

An initialization voltage line Vint may be located on the second portion PT2. The initialization voltage line Vint may be located on the third insulation layer INS3. The initialization voltage line Vint may overlap the display area DA.

The scan driving circuit SDC in FIG. 1 may be located at a boundary between the second portion PT2 and the third portion PT3. The scan driving circuit SDC may be located at the second-2 portion NIC. The scan driving circuit SDC may include a plurality of driving transistors TRP1 and TRP2 and driving signal lines VD.

Each of the driving transistors TRP1 and TRP2 may include a semiconductor pattern SP, a control electrode E1, an input electrode E2, and an output electrode E3. The driving transistors TRP1 and TRP2 may be arranged through the same process as the transistors TR connected to the light emitting elements OLED. In a plan view, the driving transistors TRP1 and TRP2 may not overlap the transistors TR connected to the light emitting elements OLED.

The semiconductor patterns SP may be located on the buffer layer BFL. The first insulation layer INS1 may cover the semiconductor patterns SP. Control electrodes E1 may be located on the first insulation layer INS1. The second insulation layer INS2 may cover the control electrodes E1. The third insulation layer INS3 may be located on the second insulation layer INS2. The input electrode E2 and the output electrode E3 may be located on the third insulation layer INS3. The input electrode E2 and the output electrode E3 may be connected to the semiconductor patterns SP through a seventh contact hole CH7 defined in the first to third insulation layers INS1 to INS3. The fourth insulation layer INS4 may be located on the third insulation layer INS3 to cover the input electrode E2 and the output electrode E3. The fifth insulation layer INS5 may be located on the fourth insulation layer INS4.

A driving signal line VD may be located on the fifth insulation layer INS3. The driving signal line VD may include first, second, and third lines V1, V2, and V3. The first line V1, the second line V2, and the third line V3 may be arranged in the first direction DR1. The first line V1 may have a surface area relatively greater than that of each of the second line V2 and the third line V3. The first to third lines V1 to V3 may transmit signals that are independent from each other.

The first line V1 may transmit a constant voltage to the first driving transistor TRP1. The first line V1 may be connected to the output electrode E3 through an eighth contact hole CH8. The constant voltage may include a gate low voltage or a gate high voltage. However, this is illustrative, and the first line V1 may be one of various lines that apply the constant voltage to the scan driving circuit SDC. However, the embodiments of the present disclosure are not limited thereto.

For example, in a plan view, the first line V1 may overlap the light emitting element OLED-B32. The first line V1 may electrically shield the light emitting element OLED-B32 and the scan driving line. The first line V1 may prevent limitations in which noises occur in the light emitting element OLED-B32 due to the driving transistors TRP1 and TRP2. Thus, a process may be simplified because a portion of the driving signal lines VD is used as a shielding electrode instead of adding an electrode for electrical shielding between the light emitting element OLED-B32 and the scan driving line.

A first power voltage line VL1 may be located on the third insulation layer INS3. A power voltage pattern VSS may be located on the first line V1. The power voltage pattern VSS may be located on the fifth insulation layer INS5. A portion of the power voltage pattern VSS may be inclined along the fourth insulation layer INS4 and the fifth insulation layer INS5. The power voltage pattern VSS may be located on the same layer as the first power voltage line VL1. The power voltage pattern VSS may be located on the third portion PT3. The power voltage pattern VSS may overlap the non-display area NDA. The power voltage pattern VSS is connected to the first power line VL1 and receives a first power voltage. Hereinafter, the scan driving circuit SDC may be defined as a driving unit SDC.

The display panel DP (refer to FIG. 3) may include a plurality of dams P0 and P1. The dams P0 and P1 may be arranged along an edge of the display area DA on the plane. The dams P0 and P1 may prevent overflow of the organic layer. The dams P0 and P1 may include a first dam P0 and a second dam P1. The first dam P0 and the second dam P1 may be arranged in the first direction DR1.

The first dam P0 may be relatively more adjacent to the display area DA than the second dam P1. The first dam P0 may overlap the first power line VL1. The first dam P0 may include a first layer P01, a second layer P02, and a third layer P03. Each of the first layer P01, the second layer P02, and the third layer P03 may include an insulating material.

The second dam P1 is relatively further spaced from the display area DA than each of the dams P0 and P1. According to some embodiments, the second dam P1 may include a first layer P11, a second layer P12, a third layer P13, and a fourth layer P14.

The first dam P0 and the second dam P1 may have the same layer structure, or an additional dam may be further located on the non-display area NDA in addition to the first dam P0 and the second dam P1. However, the embodiments of the present disclosure are not limited thereto.

The thin-film encapsulation layer TFE may be located on the light emitting elements OLED. The first encapsulation layer EN1 may extend onto an edge adjacent to one side of the third portion PT3. The first encapsulation layer EN1 may overlap the display area DA and the non-display area NDA. The first encapsulation layer EN1 may be located on the second portion PT2 and the third portion PT3. The first encapsulation layer EN1 may cover the second electrode CE2, the first dam P0, and the second dam P1.

The second encapsulation layer EN2 may be located on the first encapsulation layer EN1. The second encapsulation layer EN2 may extend onto an edge adjacent to the other side of the third portion PT3. The second encapsulation layer EN2 may extend to one side of the first dam P0. One side of the first dam P0 may be defined as a side opposite to the other side facing the second dam P1.

The third encapsulation layer EN3 may be located on the second encapsulation layer EN2. The third encapsulation layer EN3 may extend onto an edge adjacent to one side of the third portion PT3. The third encapsulation layer EN3 may overlap the display area DA and the non-display area NDA. The third encapsulation layer EN3 may be located on the second portion PT2 and the third portion PT3. The third encapsulation layer EN3 may be located on the second electrode CE2, the first dam P0, and the second dam P1.

FIGS. 7A to 7D are plan views illustrating the pixel element layer in FIG. 6.

For example, FIGS. 7A, 7C, and 7D are plan views sequentially illustrating circuit units (or circuits) ICU arranged in a direction away from the first portion PT1.

For example, FIG. 7B is a plan view illustrating one circuit unit ICU in FIG. 7A.

Referring to FIGS. 2, 6, and 7A to 7D, each of the second pixels PX may include a circuit unit ICU and a light emitting element MU. The circuit units ICU may be arranged in the first direction DR1. The circuit units may be sequentially arranged in the direction away from the first portion PT1. For example, first to fifteenth units ICU1 to ICU15 are illustrated. The circuit unit ICU adjacent to the first portion PT1 may be a first circuit unit ICU1. The circuit unit ICU that is most spaced apart from the first portion PT1 may be a fifteenth circuit unit ICU15. However, the embodiments of the present disclosure are not limited thereto. For example, a relatively greater number of circuit units ICU may be located on the second portion PT2.

In a plan view, the circuit units ICU may overlap the light emitting units MU. Each of the light emitting units MU may have a size greater than that of each of the circuit units ICU. Two circuit units ICU adjacent to each other in the first direction DR1 may overlap one light emitting unit MU. The circuit units ICU may be arranged from an area overlapping a first light emitting unit MU1 and an area overlapping an eighth light emitting unit MU8.

Hereinafter, an area of the second portion PT2, on which the circuit units ICU are located, may be defined as a second-1 portion YIC, and an area of the second portion PT2, on which the circuit units ICU are not located, may be defined as a second-2 portion NIC. The pixel circuit PC of FIG. 2 may be located on a second-1 portion YIC. The pixel circuit PC of FIG. 2 may not be located on a second-2 portion NIC. According to some embodiments, the second-2 portion NIC may overlap the scan driving circuit SDC in FIG. 6. Hereinafter, one circuit unit ICU among the circuit units ICU will be described.

According to some embodiments, the circuit units ICU may include the pixel circuit PC in FIG. 2. Each of the circuit units ICU may include a plurality of transistors TR. For example, four fourth contact holes CH4 are defined in the circuit units ICU, respectively. Each of the four fourth contact holes CH4 may be the fourth contact hole CH4 used in the transistor TR in FIG. 6. That is, the four fourth contact holes CH4 may be connected to four sixth transistors T6, respectively. The sixth transistors T6 may be connected to the first to fifth and seventh transistors T1 to T5 and T7 and at least one capacitor in FIG. 2.

Each of the circuit units ICU may include four pixel circuits PC, and one fourth contact hole CH4 may be used in the sixth transistor T6 of each of the pixel circuits DP-CL. The sixth transistor T6 of each of the pixel circuits DP-CL shown in FIG. 5 may be connected to the corresponding light emitting elements OLED by the fourth contact hole CH4.

FIGS. 8A to 8H are views for explaining the first extension lines connected to the circuit units.

For example, each of the first extension lines EX1 are simply illustrated by a thick solid line, and each of the transistors TR are illustrated by a thin solid line.

For example, FIGS. 8A, and 8G are plan views illustrating the first to fifteenth circuit units ICU1 to ICU15 in an order.

For example, FIG. 8B is an enlarged plan view illustrating the first circuit unit ICU1 and the first light emitting unit MU1.

For example, FIG. 8C is an enlarged plan view illustrating the second circuit unit ICU2 and the second light emitting unit MU2.

For example, FIG. 8D is an enlarged plan view illustrating the third circuit unit ICU3 and the third light emitting unit MU3.

For example, FIG. 8E is an enlarged plan view illustrating the fourth circuit unit ICU4 and the fourth light emitting unit MU4.

For example, FIG. 8F is an enlarged plan view illustrating the fifth circuit unit ICU5 and the fifth light emitting unit MU5.

For example, a rectangular box in FIG. 8B may indicate the first area A1 in FIG. 6, and an X-mark in the rectangular box may indicate the fourth contact hole CH4 in FIG. 6.

Because the circuit units ICU and the fourth contact holes CH4 in FIGS. 8A to 8C are the same as the transistors in FIGS. 7A to 7C, descriptions thereof will be omitted or simply provided.

Referring to FIGS. 3, 4, 8A, and 8B, the second pixels PX2 of FIG. 3 may include the first extension lines EX1. The first extension lines EX1 may be located in the fourth contact holes CH4 defined in the circuit units ICU. Each of the first extension lines EX1 may be connected to the corresponding transistor TR among the transistors TR through the fourth contact holes CH4.

The first extension lines EX1 may indicate a portion arranged from the fourth contact holes CH4 to the first area A1 as described in FIG. 6. A length of each of the first extension lines EX1 may decrease when the fourth contact holes CH4 are adjacent to the first area A1 and increase when the fourth contact holes CH4 are spaced apart from the first area A1.

The first extension lines EX1 connected to the first circuit unit ICU1 may overlap the first light emitting unit MU1. As illustrated in FIG. 8B, the first extension lines EX1 connected to the first circuit unit ICU1 may overlap the first circuit unit ICU1. Also, the length of each of the first extension lines EX1 overlapping the first circuit unit ICU1 may be set to a minimum value.

The first extension lines EX1 connected to k-th circuit units ICU except for the first circuit unit ICU1 may overlap the k-th circuit units ICU. Here, k is an even number of natural numbers equal to or greater than 2. Also, k may increase in the direction away from the first portion PT1.

According to some embodiments, the length of each of the first extension lines EX1 overlapping the first circuit unit ICU1 may be equal to that of each of the first extension lines EX1 overlapping the k-th circuit units ICU.

For example, referring to FIGS. 8C to 8E, the first extension lines EX1 connected to the second circuit unit ICU2 may overlap the second circuit unit ICU2, and the first extension lines EX1 connected to the fourth circuit unit ICU4 may overlap the fourth circuit unit ICU4. That is, the first extension lines EX1 connected to the second circuit unit ICU2 may extend to the second light emitting unit MU2. Also, the first extension lines EX1 connected to the fourth circuit unit ICU4 may not extend to the fourth light emitting unit MU4.

The first extension lines EX1 connected to k+1-th circuit units ICU except for the first circuit unit ICU1 may extend until the k+1-th light emitting units MU. Here, k may increase in the direction away from the first portion PT1.

For example, referring to FIG. 8D, the first extension lines EX1 connected to the third circuit unit ICU3 may extend to the third light emitting unit MU3. For example, each of the first extension lines EX1 may extend from the corresponding fourth contact hole CH4 among the fourth contact holes CH4 located on the third circuit unit ICU3 to the corresponding first area A1 among the first areas A1 located on the third light emitting unit MU3.

Also, referring to FIG. 8F, each of the first extension lines EX1 may extend from the corresponding fourth contact hole CH4 among the fourth contact holes CH4 located on the fifth circuit unit ICU5 to the corresponding first area A1 among the first areas A1 located on the fifth light emitting unit MU5.

The length of each of the first extension lines EX1 connected to the k+1 (odd number)-th circuit units ICU may increase as the k increases. The length of each of the first extension lines EX1 connected to the k (even number)-th circuit units ICU may be constant although the k increases. The length of each of the first extension lines EX1 connected to the k-th circuit units ICU may be less than that of each of the first extension lines EX1 connected to the k+1-th circuit units ICU.

Referring to FIGS. 8G and 8H, each of the first extension lines EX1 may be located in the corresponding fourth contact hole CH4 among the fourth contact holes CH4. Each of the first extension lines EX1 may be connected to the corresponding transistor TR among the transistors TR through the fourth contact holes CH4. As described above, the first extension lines EX1 connected to the k-th circuit units ICU may overlap the k-th circuit units ICU. The first extension lines EX1 connected to the k+1-th circuit units ICU may extend to the k+1-th light emitting units MU.

FIGS. 9A to 9H are views for explaining the second extension lines connected to the circuit units.

For example, each of the second extension lines EX2 are simply illustrated by a thick solid line, and each of the first extension lines EX1 and the transistors TR are illustrated by a thin solid line.

For example, FIGS. 9A and 9G are plan views illustrating the first to fifteenth circuit units ICU1 to ICU15 in an order.

For example, FIG. 9B is an enlarged plan view illustrating the first circuit unit ICU1 and the first light emitting unit MU1.

For example, FIG. 9C is an enlarged plan view illustrating the second circuit unit ICU2 and the second light emitting unit MU2.

For example, FIG. 9D is an enlarged plan view illustrating the third circuit unit ICU3 and the third light emitting unit MU3.

For example, FIG. 9E is an enlarged plan view illustrating the fourth circuit unit ICU4 and the fourth light emitting unit MU4.

For example, FIG. 9F is an enlarged plan view illustrating the fifth circuit unit ICU5 and the fifth light emitting unit MU5.

For example, a rectangular box in FIGS. 9A to 9H may indicate the second area A2 in FIG. 6, and an X-mark in the rectangular box may indicate the fourth contact hole CH4 and the fifth contact hole CH5 in FIG. 6.

Referring to FIGS. 3, 4, 9A, and 9B, the second pixels PX2 may include the second extension lines EX2. The second extension lines EX2 may be located in the fifth contact holes CH5 defined in the circuit units ICU. The fifth contact holes CH5 may overlap the first area A1 in FIG. 8A. Each of the second extension lines EX2 may be connected to the corresponding transistor TR among the transistors TR through the fifth contact holes CH5.

The second extension lines EX2 may indicate a portion arranged from the fifth contact holes CH5 to the second area A2 as described in FIG. 6. A length of each of the second extension lines EX2 may decrease when the fifth contact holes CH5 are adjacent to the second area A2 and increase when the fifth contact holes CH5 are spaced apart from the second area A2.

The second extension lines EX2 connected to the first circuit unit ICU1 may overlap the first light emitting unit MU1. As illustrated in FIG. 9B, the second extension lines EX2 connected to the first circuit unit ICU1 may overlap the first circuit unit ICU1. Also, the length of each of the second extension lines EX2 overlapping the first circuit unit ICU1 may be set to a minimum value. The length of each of the second extension lines EX2 connected to the first circuit unit ICU1 may be equal (or substantially equal) to that of each of the first extension lines EX1 in FIG. 8B.

The second extension lines EX2 connected to k-th circuit units ICU except for the first circuit unit ICU1 may extend until the k-th light emitting units MU. Here, k may increase in the direction away from the first portion PT1. The length of each of the second extension lines EX2 connected to the k-th circuit units ICU may increase as the k increases.

For example, referring to FIG. 9C, the second extension lines EX2 connected to the second circuit unit ICU2 may extend to the second light emitting unit MU2. For example, each of the second extension lines EX2 may extend from the corresponding fifth contact hole CH5 among the fifth contact holes CH5 located on the second circuit unit ICU2 to the corresponding second area A2 among the second areas A2 located on the second light emitting unit MU2.

Also, referring to FIG. 9E, the second extension lines EX2 connected to the fourth circuit unit ICU4 may extend to the fourth light emitting unit MU4. For example, each of the second extension lines EX2 may extend from the corresponding fifth contact hole CH5 among the fifth contact holes CH5 located on the fourth circuit unit ICU4 to the corresponding second area A2 among the second areas A2 located on the fourth light emitting unit MU4.

The length of each of the second extension lines EX2 connected to the k+1-th circuit units ICU may be constant although the k increases. The length of each of the second extension lines EX2 connected to the k+1-th circuit units ICU may be less than that of each of the second extension lines EX2 connected to the k-th circuit units ICU. According to some embodiments, the length of each of the second extension lines EX2 overlapping the first circuit unit ICU1 may be equal to that of each of the second extension lines EX2 overlapping the k+1-th light emitting units MU.

For example, referring to FIGS. 9D and 9F, the second extension lines EX2 connected to the third circuit unit ICU3 may overlap the third light emitting unit MU3, and the second extension lines EX2 connected to the fifth circuit unit ICU5 may overlap the fifth light emitting unit MU5.

The length of each of the first extension lines EX1 connected to the first circuit unit ICU1 may be equal to that of each of the second extension lines EX2 connected to the first circuit unit ICU1. The length of each of the first extension lines EX1 connected to the k-th circuit units ICU may be different from that of each of the second extension lines EX2 connected to the k-th circuit units ICU.

The length of each of the first extension lines EX1 connected to the k+1-th circuit units ICU may be different from that of each of the second extension lines EX2 connected to the k+1-th circuit units ICU. Specifically, the length of each of the first extension lines EX1 connected to the k-th circuit units ICU may be less than that of each of the second extension lines EX2 connected to the k-th circuit units ICU. The length of each of the first extension lines EX1 connected to the k+1-th circuit units ICU may be greater than that of each of the second extension lines EX2 connected to the k-th circuit units ICU.

Referring to FIGS. 9G and 9H, each of the second extension lines EX2 may be located in the corresponding fifth contact hole CH5 among the fifth contact holes CH5. Each of the second extension lines EX2 may be connected to the corresponding transistor TR among the transistors TR through the fifth contact holes CH5. As described above, the second extension lines EX2 connected to the k+1-th circuit units ICU may overlap the k+1-th circuit units ICU. The second extension lines EX2 connected to the k-th circuit units ICU may extend to the k+1-th light emitting units MU.

The circuit units ICU may be connected to the corresponding light emitting unit MU among the light emitting units MU through one extension line. As the k increases, a planar distance between the circuit units ICU and the light emitting units MU may increase. When the k increases, the length of each of the extension lines located on the second portion PT2 may increase. When the length of each of the extension lines located on the second portion PT2 increases, a spatial limitation may exist. Thus, the extended length of each of the extended extension lines may be limited, and the circuit units ICU and the light emitting units MU, which are spaced apart from each other, may not be connected. Thus, extension of the display area DA of FIG. 3 may be limited.

However, according to some embodiments of the present disclosure, when the circuit units ICU are connected to the light emitting units MU through the first extension lines EX1 and the second extension lines EX2, the length of each of the first extension lines EX1 connected to the k-th circuit units ICU may be different from that of each of the first extension lines EX1 connected to the k+1-th circuit units ICU. The length of each of the second extension lines EX2 connected to the k-th circuit units ICU may be different from that of each of the second extension lines EX2 connected to the k+1-th circuit units ICU. Also, the first extension lines EX1 and the second extension lines EX2 connected to the k-th circuit units ICU may have different lengths, and the first extension lines EX1 and the second extension lines EX2 connected to the k+1-th circuit units ICU may have different lengths. Due to the above-described structure, the more first and second extension lines EX1 and EX2 may be located in a limited area, and the more circuit units ICU and light emitting units MU may be connected by the extension lines EX1 and EX2. Accordingly, a spaced distance between the circuit units ICU and the light emitting units MU may increase, and as the light emitting units MU are located on the driving unit SDC, the circuit units ICU may be connected to the light emitting units MU until an area adjacent to the non-display area NDA. Thus, the display area DA of FIG. 3 may be further extended.

FIG. 10 is a view illustrating the light emitting units located on the second portion.

For example, FIG. 10 is a plan view.

For example, in FIG. 10, the first electrode AE connecting the light emitting elements emitting the same color is illustrated by a dotted line.

Referring to FIGS. 2, 6, and 10, the light emitting units MU may be connected to the circuit units ICU through the first extension lines EX1 and the second extension lines EX2. The k-th circuit units ICU may be connected to the corresponding light emitting unit MU among the k-th light emitting units MU. The k+1-th circuit units ICU may be connected to the corresponding light emitting unit MU among the k+1-th light emitting units MU. Here, k is an even number of natural numbers greater than 1 and less than 15. The light emitting elements OLED-R12, OLED-G22, OLED-B32, and OLED-G42 may be connected to the circuit units ICU.

Each of the pixel circuits PC may be connected to the corresponding light emitting element OLED-R11, OLED-G21, OLED-G22, and OLED-B31 among the light emitting elements OLED-R11, OLED-G21, OLED-G22, and OLED-B31 located in the same row. The circuit units ICU located in a h-th row may be connected to the light emitting elements OLED-R11, OLED-G21, OLED-G22, and OLED-B31 located in the h-th row.

For example, each of the pixel circuits PC located in a first row ROW1 of the first circuit unit ICU1 may be connected to the corresponding light emitting element OLED-R11, OLED-G21, OLED-G22, and OLED-B31 among the light emitting elements OLED-R11, OLED-G21, OLED-G22, and OLED-B31 located in the first row ROW1. Each of the pixel circuits PC located in a second row ROW2 of the first circuit unit ICU1 may be connected to the corresponding light emitting element OLED-R11, OLED-G21, OLED-G22, and OLED-B31 among the light emitting elements OLED-R11, OLED-G21, OLED-G22, and OLED-B31 located in the second row ROW2. The row may correspond to the first direction DR1. Here, h is a natural number.

Each of the first electrodes AE of FIG. 6 may be connected to the corresponding second extension line EX2 among the second extension lines EX2 through the sixth contact hole CH6. The first electrodes AE may be connected to the first extension lines EX1 and the drain D through the second extension lines EX2. Hereinafter, one circuit unit ICU and one light emitting unit MU will be described.

The first light emitting elements OLED-R11 may be connected to each other by the first electrode AE of one first light emitting element OLED-R11. The light emitting layers EML of the first light emitting elements OLED-R11 may be located on the first electrode AE of one first light emitting element OLED-R11. One first light emitting element OLED-R11 among the first light emitting elements OLED-R11 may be connected to the circuit unit ICU through the first and second connection lines EX1 and EX2. Another first light emitting element OLED-R11 among the first light emitting elements OLED-R11 may be connected to the circuit unit ICU through the first electrode AE.

According to some embodiments, the second-1 light emitting elements OLED-G21 may be connected to each other by the first electrode AE of one second-1 light emitting element OLED-G21. The light emitting layers EML of the second-1 light emitting elements OLED-G21 may be located on the first electrode AE of one second-1 light emitting element OLED-G21. One second-1 light emitting element OLED-G21 among the second-1 light emitting elements OLED-G21 may be connected to the circuit unit ICU through the first and second connection lines EX1 and EX2. Another second-1 light emitting element OLED-G21 among the second-1 light emitting elements OLED-G21 may be connected to the circuit unit ICU through the first electrode AE.

According to some embodiments, the second-2 light emitting elements OLED-G22 may be connected to each other by the first electrode AE of one second-2 light emitting element OLED-G22. The light emitting layers EML of the second-2 light emitting elements OLED-G22 may be located on the first electrode AE of one second-2 light emitting element OLED-G22. One second-2 light emitting element OLED-G22 among the second-2 light emitting elements OLED-G22 may be connected to the circuit unit ICU through the first and second connection lines EX1 and EX2. Another second-2 light emitting element OLED-G22 among the second-2 light emitting elements OLED-G22 may be connected to the circuit unit ICU through the first electrode AE.

According to some embodiments, the third light emitting elements OLED-B31 may be connected to each other by the first electrode AE of one third light emitting element OLED-B31. The light emitting layers EML of the third light emitting elements OLED-B31 may be located on the first electrode AE of one third light emitting element OLED-B31. One third light emitting element OLED-B31 among the third light emitting elements OLED-B31 may be connected to the circuit unit ICU through the first and second connection lines EX1 and EX2. Another third light emitting element OLED-B31 among the third light emitting elements OLED-B31 may be connected to the circuit unit ICU through the first electrode AE.

As the light emitting elements OLED-R12, OLED-G22, OLED-B32, and OLED-G42 emitting the same color are electrically connected to each other, the light emitting layers EML located on one first electrode AE may be simultaneously controlled.

Referring to FIGS. 5 and 10, each of the light emitting elements OLED-R10, OLED-G20, and OLED-B30 located on the first portion PT1 may be connected to the corresponding circuit element layer DP-CL among the circuit element layers DP-CL located on the first portion PT1.

FIG. 11 is a conceptual view for explaining a connection relationship between the light emitting units and the circuit units.

For example, a plan view illustrating the light emitting units MU and the circuit units ICU is provided.

For example, each of the first extension lines EX1 and the second extension lines EX2 is illustrated by one solid line, and the transistor TR located on each of the circuit units ICU is simply illustrated as one transistor TR.

For example, the light emitting elements OLED-R11, OLED-G21, OLED-G22, and OLED-B31 of the light emitting units MU are omitted.

Because the first and second extension lines EX1 and EX2, the light emitting units MU, and the circuit units ICU in FIG. 11 are the same as the first and second extension lines EX1 and EX2, the light emitting units MU, and the circuit units ICU in FIG. 10, descriptions thereof will be omitted or simply provided.

Referring to FIG. 11, the first circuit unit ICU1 may be connected to the first light emitting unit MU1. The k-th circuit unit ICU may be connected to the k-th light emitting unit MU. The k+1-th circuit unit ICU may be connected to the k+1-th light emitting unit MU. As the k increases, a distance between the circuit unit ICU and the light emitting unit MU may increase. Accordingly, a total sum of lengths of the extension lines EX may increase as the k increases.

According to some embodiments of the present disclosure, the light emitting units located on the second portions may be connected to the corresponding circuit units, respectively, among the plurality of circuit units by the first extension lines and the second extension lines. In the direction away from the first portion, the k-th circuit unit may be connected to the k-th light emitting unit, and the k+1-th circuit unit may be connected to the k+1-th light emitting unit. K is an even number of natural numbers greater than about 1. The length of each of the first extension lines connecting the k-th circuit unit and the k-th light emitting unit may be less than that of each of the second extension lines. The length of each of the first extension lines connecting the k+1-th circuit unit and the k+1-th light emitting unit may be greater than that of each of the second extension lines. Due to the above-described structure, the more first and second extension lines may be located in the limited area, and the more circuit units and light emitting units may be connected by the extension lines. Accordingly, the spaced distance between the circuit units and the light emitting units may increase. Thus, the display area may be further extended.

Although the embodiments of the present invention have been described, it is understood that the present invention should not be limited to these embodiments but various changes and modifications can be made by one ordinary skilled in the art within the spirit and scope of the present invention as defined in the appended claims, and their equivalents. Thus, to the maximum extent allowed by law, the scope of embodiments according to the present invention is to be determined by the broadest permissible interpretation of the following claims and their equivalents, and shall not be restricted or limited by the foregoing detailed description.

What is claimed is:

1. A display device comprising:
a substrate having a first portion and a second portion adjacent to the first portion in a first direction;
a plurality of first pixels on the first portion; and
a plurality of second pixels on the second portion,
wherein the second pixels comprise:
a plurality of light emitting units comprising a plurality of light emitting elements and arranged in the first direction;
a plurality of circuit units comprising a plurality of transistors and arranged in the first direction;
a plurality of first extension lines connected to the circuit units; and
a plurality of second extension lines connected to the first extension lines and the light emitting units,
wherein in an order of the circuit units in a direction away from the first portion, a length of each of the first extension lines connected to k+1-th circuit units is different from that of each of the first extension lines connected to k-th circuit units, and k is a natural number greater than 1.

2. The display device of claim 1, wherein in an order of the light emitting units in the direction away from the first portion, a length of each of the second extension lines connected to k+1-th light emitting units is different from that of each of the second extension lines connected to k-th light emitting units.

3. The display device of claim 2, wherein a length of each of the first extension lines connected to the k+1-th circuit units is different from that of each of the second extension lines connected to the k+1-th light emitting units.

4. The display device of claim 3, wherein a length of each of the first extension lines connected to the k-th circuit units is different from that of each of the second extension lines connected to the k-th light emitting units.

5. The display device of claim 1, wherein the first extension lines connected to a first circuit unit and the second extension lines connected to a first light emitting unit have a same length as each other.

6. The display device of claim 2, wherein the k+1-th circuit units are connected to the k+1-th light emitting units, respectively, and the k-th circuit units are connected to the k-th light emitting units, respectively.

7. The display device of claim 6, wherein a distance between the light emitting units and the circuit units, which are connected by the first and second extension lines, gradually increases in the direction away from the first portion.

8. The display device of claim 1, wherein the light emitting elements of each of the light emitting units comprise:
a plurality of first light emitting elements arranged in a first diagonal direction and connected to each other;
a plurality of second-1 light emitting elements arranged in the first direction and connected to each other;
a plurality of second-2 light emitting elements spaced apart from the second-1 light emitting elements in a second direction crossing the first direction, arranged in the first direction, and connected to each other; and
a plurality of third light emitting elements arranged in a second diagonal direction crossing the first diagonal direction and connected to each other,
wherein the second-1 and second-2 light emitting elements are adjacent to the first and third light emitting elements, and
the first diagonal direction is defined as a direction crossing the first and second directions on a plane defined by the first and second directions, and the second diagonal direction is defined as a direction crossing the first and second directions and the first diagonal direction on the plane.

9. The display device of claim 8, wherein each of the first, second-1, second-2, and third light emitting elements comprises:
a first electrode connected to a corresponding second extension line among the second extension line;
a second electrode on the first electrode; and
a light emitting layer between the first electrode and the second electrode.

10. The display device of claim 9, wherein the first light emitting elements are connected to each other by a first electrode of one first light emitting element.

11. The display device of claim 10, wherein the light emitting layers of the first light emitting elements are on the first electrode of the one first light emitting element.

12. The display device of claim 9, wherein the second-1 light emitting elements are connected to each other by a first electrode of one second-1 light emitting element,
the second-2 light emitting elements are connected to each other by the first electrode of one second-2 light emitting element,
the light emitting layers of the second-1 light emitting elements are on the first electrode of the one second-1 light emitting element, and
the light emitting layers of the second-2 light emitting elements are on the first electrode of the one second-2 light emitting element.

13. The display device of claim 9, wherein the third light emitting elements are connected to each other by a first electrode of one third light emitting element, and
the light emitting layers of the third light emitting elements are on the first electrode of the one third light emitting element.

14. The display device of claim 1, wherein the second portion comprises:
a second-1 portion adjacent to the first portion; and
a second-2 portion spaced apart from the first portion further than the second-1 portion and adjacent to the second-1 portion,
wherein the transistors are on the second-1 portion and are not on the second-2 portion.

15. The display device of claim 14, further comprising a driving unit on the second-2 portion,
wherein some light emitting units among the light emitting units overlap the driving unit in a plan view.

16. The display device of claim 1, wherein the circuit units on a h-th row are connected to the light emitting elements on the h-th row, respectively, the row corresponds the first direction, and h is a natural number.

17. A display device comprising:
a substrate having a first portion and a second portion adjacent to the first portion in a first direction; and
a plurality of pixels on the first portion and the second portion,
wherein each of the pixels on the second portion among the pixels comprises:
a plurality of light emitting units comprising a plurality of light emitting elements and arranged in the first direction;
a plurality of circuit units comprising a plurality of transistors and arranged in the first direction;
a plurality of first extension lines connected to the circuit units; and
a plurality of second extension lines connected to the first extension lines and the light emitting units,
wherein in an order of the circuit units in a direction away from the first portion, a length of each of the first extension lines connected to k-th circuit units is less than that of each of the second extension lines connected to k-th light emitting units, and k is a natural number greater than 1.

18. The display device of claim 17, wherein a length of each of the first extension lines connected to k+1-th circuit units is greater than that of each of the second extension lines connected to k+1-th light emitting units.

19. The display device of claim 17, wherein a distance between the light emitting units and the circuit units, which are connected by the first and second extension lines, gradually increases in the direction away from the first portion.

20. The display device of claim 19, wherein a sum of lengths of the first extension lines and the second extension lines gradually increases as k increases.
